(19) United States
(12) Patent Application Publication
(10) Pub. No.: US 2024/0317577 A1
(43) Pub. Date: Sep. 26, 2024

(54) MEMS ELEMENT, OPTICAL SCANNING DEVICE, AND DISTANCE MEASURING DEVICE

(71) Applicant: Mitsubishi Electric Corporation, Tokyo (JP)

(72) Inventor: Yusuke SHIRAYANAGI, Chiyoda-ku, Tokyo (JP)

(73) Assignee: Mitsubishi Electric Corporation, Tokyo (JP)

(21) Appl. No.: 18/271,675

(22) PCT Filed: Feb. 10, 2021
(86) PCT No.: PCT/JP2021/005040

§ 371 Date: Jul. 11, 2023

(51) Int. Cl. B81B 7/00; B81C 1/00

(52) U.S. Cl. CPC B81B 7/0006; B81C 1/00095; B81B 2201/042; B81B 2203/0109; B81B 2203/04; B81B 2207/096; B81C 2201/0132; B81C 2201/0176; B81C 2201/0198

(57) ABSTRACT

An optical scanning device, which is a MEMS element, includes a first insulating layer, a first semiconductor layer, a second insulating layer, and a second semiconductor layer that are laminated in this order, a first doped region formed at an interface between the first insulating layer and the first semiconductor layer, a second doped region formed at an interface between the first semiconductor layer and the second insulating layer, and a first wiring portion and a second wiring portion disposed on the first insulating layer apart from each other. The first doped region and the second doped region are electrically connected in parallel between the first wiring portion and the second wiring portion.

### TECHNICAL FIELD

The present disclosure relates to a MEMS element, an optical scanning device, a distance measuring device, and a MEMS element manufacturing method.

### BACKGROUND ART

Micro electro mechanical system (MEMS) elements such as a pressure sensor, an optical scanning device (optical scanner), an acceleration sensor, a gyroscope, a vibration power generation element, an ultrasonic sensor, and an infrared sensor are known. In general, such a MEMS element is manufactured using a silicon on insulator (SOI) substrate. The SOI substrate is a substrate in which a silicon layer (active layer) is formed on a silicon support substrate (support layer) with an oxide film interposed between the silicon layer and the silicon support substrate.

The MEMS element is known for a case where physical properties of wiring change. For example, the optical scanning device generally includes a reflector that reflects light, a support that supports the reflector, a drive beam that connects the reflector and the support, and a drive portion that drives the reflector to rotate the reflector around an axis of the drive beam. As the drive portion, a drive portion of an electromagnetic drive type, a drive portion of an electrostatic drive type, or a drive portion of a piezoelectric drive type is known. In any drive type, wiring for connecting a first conductive portion disposed in the reflector and a second conductive portion disposed in the support is disposed in the drive beam. Therefore, for example, when the reflector is driven at a relatively wide deflection angle, a relatively large stress is applied to the wiring on the drive beam, thereby causing a change in physical properties of the wiring.

Japanese Patent Laying-Open No. 2010-98905 discloses a planar actuator in which a plurality of separate wiring patterns formed on drive beams are electrically connected by a diffusion conduction portion serving as an auxiliary conductor formed by diffusing an impurity into a semiconductor material constituting the drive beam.

### CITATION LIST

### Patent Literature

PTL 1: Japanese Patent Laying-Open No. 2010-98905

### SUMMARY OF INVENTION

### Technical Problem

In general, the diffusion conduction portion, however, is higher in sheet resistance value than a wiring portion made of a silicide or metal. Therefore, in a case where a high current flows through the diffusion conduction part, there is concern about heat generation in the diffusion conduction portion.

It is therefore a main object of the present disclosure to provide a MEMS element, an optical scanning device, and a distance measuring device including a wiring portion having a relatively low sheet resistance value while suppressing a change in physical properties.

### Solution to Problem

A MEMS element according to the present disclosure includes a first insulating layer, an active layer, a second insulating layer, and a support layer that are laminated in this order, a first doped region and a second doped region formed at any one of an interface between the first insulating layer and the active layer, an interface between the active layer and the second insulating layer, and an interface between the second insulating layer and the support layer, and disposed apart from each other in a laminating direction of the first insulating layer, the active layer, the second insulating layer, and the support layer, and a first conductive portion and a second conductive portion disposed apart from each other on the first insulating layer. The first doped region and the second doped region are electrically connected in parallel between the first conductive portion and the second conductive portion.

An optical scanning device according to the present disclosure includes a reflector having a reflection surface, a support disposed apart from the reflector, a drive beam connecting the reflector and the support, and a drive portion to drive the reflector to twist the reflector around the drive beam relative to the support. The drive portion includes a first conductive portion disposed in the reflector, a second conductive portion disposed in the support, and a wiring portion disposed at least in the drive beam and connecting the first conductive portion and the second conductive portion. The drive beam includes a first insulating layer, a semiconductor layer, and a second insulating layer that are laminated in this order, a first doped region formed at an interface between the first insulating layer and the semiconductor layer, and a second doped region formed at an interface between the semiconductor layer and the second insulating layer. The first doped region and the second doped region serve as at least a part of the wiring portion, and are electrically connected in parallel between the first conductive portion and the second conductive portion.

A MEMS element manufacturing method according to the present disclosure includes preparing an SOI substrate including a first insulating layer, an active layer, a second insulating layer, and a support layer that are laminated in this order, and a first doped region and a second doped region formed at any one of an interface between the first insulating layer and the active layer, an interface between the active layer and the second insulating layer, and an interface between the second insulating layer and the support layer, and disposed apart from each other in a laminating direction of the first insulating layer, the active layer, the second insulating layer, and the support layer, and forming a first conductive portion disposed on the first insulating layer and connected to each of the first doped region and the second doped region, and a second conductive portion disposed on the first insulating layer apart from the first conductive portion and connected to the first conductive portion through each of the first doped region and the second doped region. The preparing an SOI substrate includes forming the second doped region on a first surface of the active layer, forming an insulating film on at least one of the first surface on which the second doped region is formed or a second surface of the support layer, and bonding the active layer and the support layer together with the insulating film interposed between the active layer and the support layer.

### ADVANTAGEOUS EFFECTS OF INVENTION

According to the present invention, it is possible to provide a MEMS element, an optical scanning device, and a distance measuring device including wiring having a low sheet resistance value while suppressing a change in physical properties.

### BRIEF DESCRIPTION OF DRAWINGS

FIG. 1 is a perspective view of an optical scanning device according to a first embodiment.

FIG. 2 is a plan view of the optical scanning device illustrated in FIG. 1.

FIG. 3 is a combined cross-sectional view taken along a cross-sectional line IIIa-IIIa, a cross-sectional line IIIb-IIIb, and a cross-sectional line IIIc-IIIc illustrated in FIG. 2.

FIG. 4 is a cross-sectional view illustrating a process of a method for manufacturing the optical scanning device according to the first embodiment.

FIG. 5 is a cross-sectional view illustrating a process, subsequent to the process illustrated in FIG. 4, of the method for manufacturing the optical scanning device according to the first embodiment.

FIG. 6 is a cross-sectional view illustrating a process, subsequent to the process illustrated in FIG. 5, of the method for manufacturing the optical scanning device according to the first embodiment.

FIG. 7 is a cross-sectional view illustrating a process, subsequent to the process illustrated in FIG. 6, of the method for manufacturing the optical scanning device according to the first embodiment.

FIG. 8 is a cross-sectional view illustrating a process, subsequent to the process illustrated in FIG. 7, of the method for manufacturing the optical scanning device according to the first embodiment.

FIG. 9 is a cross-sectional view illustrating a process, subsequent to the process illustrated in FIG. 8, of the method for manufacturing the optical scanning device according to the first embodiment.

FIG. 10 is a cross-sectional view illustrating a process, subsequent to the process illustrated in FIG. 9, of the method for manufacturing the optical scanning device according to the first embodiment.

FIG. 11 is a cross-sectional view illustrating a process, subsequent to the process illustrated in FIG. 10, of the method for manufacturing the optical scanning device according to the first embodiment.

FIG. 12 is a cross-sectional view illustrating a process, subsequent to the process illustrated in FIG. 11, of the method for manufacturing the optical scanning device according to the first embodiment.

FIG. 13 is a cross-sectional view illustrating a process, subsequent to the process illustrated in FIG. 12, of the method for manufacturing the optical scanning device according to the first embodiment.

FIG. 14 is a cross-sectional view illustrating a process, subsequent to the process illustrated in FIG. 13, of the method for manufacturing the optical scanning device according to the first embodiment.

FIG. 15 is a cross-sectional view illustrating a process, subsequent to the process illustrated in FIG. 14, of the method for manufacturing the optical scanning device according to the first embodiment.

FIG. 16 is a cross-sectional view illustrating a process, subsequent to the process illustrated in FIG. 15, of the method for manufacturing the optical scanning device according to the first embodiment.

FIG. 17 is a perspective view of an optical scanning device according to a second embodiment.

FIG. 18 is a plan view of the optical scanning device illustrated in FIG. 17.

FIG. 19 is a combined cross-sectional view taken along a cross-sectional line XIXa-XIXa, a cross-sectional line XIXb-XIXb, cross-sectional lines XIXc-XIXc and XIXd-XIXd, and a cross-sectional line XIXe-XIXe illustrated in FIG. 18.

FIG. 20 is a cross-sectional view illustrating a process of a method for manufacturing the optical scanning device according to the second embodiment.

FIG. 21 is a cross-sectional view illustrating a process, subsequent to the process illustrated in FIG. 20, of the method for manufacturing the optical scanning device according to the second embodiment.

FIG. 22 is a cross-sectional view illustrating a process, subsequent to the process illustrated in FIG. 21, of the method for manufacturing the optical scanning device according to the second embodiment.

FIG. 23 is a cross-sectional view illustrating a process, subsequent to the process illustrated in FIG. 22, of the method for manufacturing the optical scanning device according to the second embodiment.

FIG. 24 is a cross-sectional view illustrating a process, subsequent to the process illustrated in FIG. 23, of the method for manufacturing the optical scanning device according to the second embodiment.

FIG. 25 is a cross-sectional view illustrating a process, subsequent to the process illustrated in FIG. 24, of the method for manufacturing the optical scanning device according to the second embodiment.

FIG. 26 is a cross-sectional view illustrating a process, subsequent to the process illustrated in FIG. 25, of the method for manufacturing the optical scanning device according to the second embodiment.

FIG. 27 is a cross-sectional view illustrating a process, subsequent to the process illustrated in FIG. 26, of the method for manufacturing the optical scanning device according to the second embodiment.

FIG. 28 is a cross-sectional view illustrating a process, subsequent to the process illustrated in FIG. 27, of the method for manufacturing the optical scanning device according to the second embodiment.

FIG. 29 is a cross-sectional view illustrating a process, subsequent to the process illustrated in FIG. 28, of the method for manufacturing the optical scanning device according to the second embodiment.

FIG. 30 is a cross-sectional view illustrating a process, subsequent to the process illustrated in FIG. 29, of the method for manufacturing the optical scanning device according to the second embodiment.

FIG. 31 is a cross-sectional view illustrating a process, subsequent to the process illustrated in FIG. 30, of the method for manufacturing the optical scanning device according to the second embodiment.

FIG. 32 is a cross-sectional view illustrating a process, subsequent to the process illustrated in FIG. 31, of the method for manufacturing the optical scanning device according to the second embodiment.

FIG. 33 is a schematic diagram of a distance measuring device to which an optical scanning device is applied with the distance measuring device mounted on a vehicle according to a third embodiment.

FIG. 34 is a diagram schematically illustrating a structure of the distance measuring device in the same embodiment.

### DESCRIPTION OF EMBODIMENTS

With reference to the drawings, embodiments of the present disclosure will be described below. Note that, in the following drawings, the same or corresponding parts are denoted by the same reference numerals to avoid the description from being redundant.

### First Embodiment

### <Configuration of Optical Scanning Device 1>

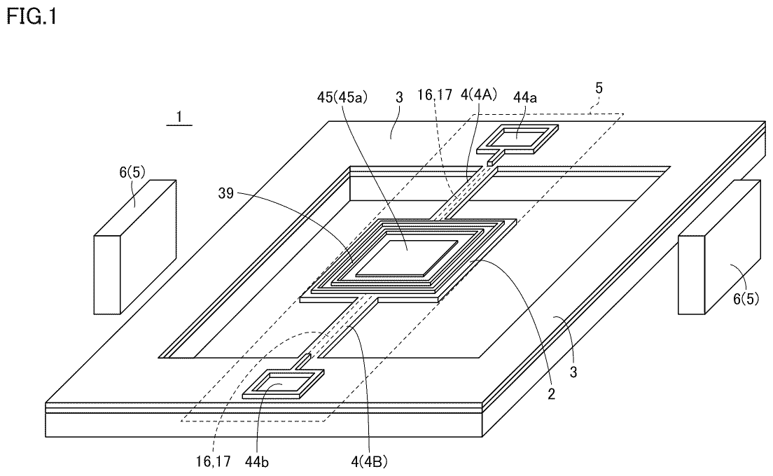

An optical scanning device 1 will be described as an example of a MEMS element according to a first embodiment. As illustrated in FIG. 1, optical scanning device 1 includes reflector 2 as a MEMS mirror, a support 3, a plurality of (for example, two) drive beams 4, and a drive portion 5. In optical scanning device 1 of the first embodiment, reflector 2 is driven around one axis.

Reflector 2 has a reflection surface 45a of a reflection film 45. Reflection surface 45a is exposed on reflector 2, for example. Reflection surface 45a is higher in reflectivity to scanned light than the other surface (for example, a front surface of a fourth insulating layer 36 to be described later) of reflector 2.

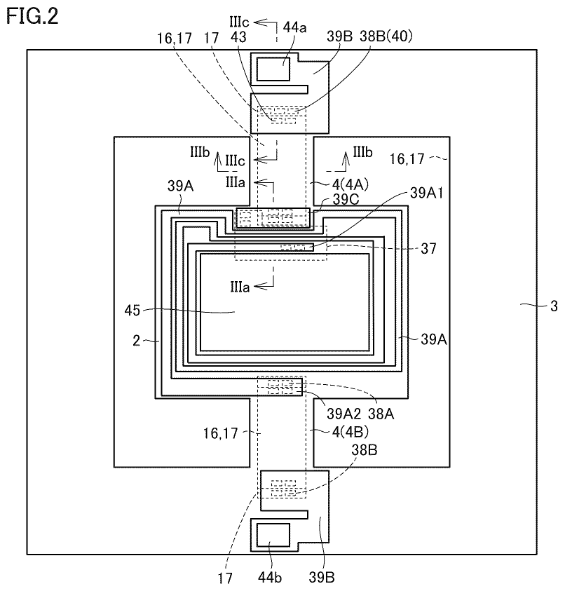

As illustrated in FIG. 2, support 3 is disposed apart from reflector 2 in plan view. In plan view, support 3 is disposed so as to surround reflector 2, for example. The plan view of optical scanning device 1 means that optical scanning device 1 is viewed from a direction that is perpendicular to reflection surface 45a and in which reflection surface 45a faces as illustrated in FIG. 2.

Each drive beam 4 connects reflector 2 and support 3. In plan view, drive beams 4 are disposed such that reflector 2 is interposed between drive beams 4 in a first direction. Each drive beam 4 has one end in the first direction connected to reflector 2. Each drive beam 4 has the other end in the first direction connected to support 3.

Drive portion 5 is, for example, a drive portion of an electromagnetic drive type. Drive portion 5 drives reflector 2 to twist reflector 2 relative to support 3 around drive beams 4. Drive portion 5 includes a first wiring portion 39A, a third wiring portion 39C, and a second wiring 37 as a first conductive portion disposed in reflector 2, a second wiring portion 39B and electrode pads 44a and 44b as a second conductive portion disposed in support 3, a plurality of sets (for example, two sets) of a first doped region 16 and a second doped region 17 as a wiring portion disposed in each drive beam 4 and electrically connecting the first conductive portion and the second conductive portion, and a pair of magnets 6.

The plurality of sets of first doped region 16 and second doped region 17 include a first set of first doped region 16 and second doped region 17 disposed in reflector 2, support 3, and one drive beam 4A, and a second set of first doped region 16 and second doped region 17 disposed in reflector 2, support 3, and other drive beam 4B. In plan view, first doped region 16 and second doped region 17 of each set are each disposed linearly along the first direction. First doped region 16 and second doped region 17 of each set have their respective one ends in the first direction disposed in reflector 2. First doped region 16 and second doped region 17 of each set have their respective other ends in the first direction disposed in support 3. First doped region 16 and the second doped region 17 of each set extend over each of the drive beams 4A and 4B.

As illustrated in FIG. 2, in plan view, first wiring portion 39A is disposed in a coil shape along an outer peripheral edge of reflector 2, Note that, in FIG. 1, a first wiring 39 is simply illustrated. In plan view, first wiring portion 39A has one end disposed on an inside of the other end of first wiring portion 39A (adjacent to reflection film 45).

As illustrated in FIG. 2, first wiring portion 39A has the one end electrically connected to one end of first doped region 16 of the first set through second wiring 37 and third wiring portion 39C at a portion of reflector 2 connected to one drive beam 4A. Furthermore, first wiring portion 39A has the one end electrically connected to one end of second doped region 17 of the first set through second wiring 37, third wiring portion 39C, and a plug 38A at the portion of reflector 2 connected to one drive beam 4A.

As illustrated in FIG. 2, first wiring portion 39A has the other end electrically connected to one end of first doped region 16 of the second set at a portion of reflector 2 connected to other drive beam 4B. Furthermore, first wiring portion 39A has the other end electrically connected to one end of second doped region 17 of the second set through a plug 38B at the portion of reflector 2 connected to other drive beam 4B.

In other words, a connection structure between the other end of first wiring portion 39A and each of first doped region 16 and second doped region 17 of the second set is basically identical in configuration to a connection structure between the one end of first wiring portion 39A and each of first doped region 16 and second doped region 17 of the first set. The connection structure between the other end of first wiring portion 39A and each of first doped region 16 and second doped region 17 of the second set is different from a connection structure between the one end of first wiring portion 39A and each of first doped region 16 and second doped region 17 of the first set in that first wiring portion 39A has the other end electrically connected to each of first doped region 16 and second doped region 17 of the second set without second wiring 37 as a jumper wiring.

As illustrated in FIG. 2, one second wiring portion 39B has one end electrically connected to the other end of first doped region 16 of the first set at a portion of support 3 connected to one drive beam 4A. Furthermore, one second wiring portion 39B has the one end electrically connected to the other end of second doped region 17 of the first set through a plug 38C at the portion of support 3 connected to one drive beam 4A. One second wiring portion 39B has the other end electrically connected to electrode pad 44a.

As illustrated in FIG. 2, other second wiring portion 39B has one end electrically connected to the other end of first doped region 16 of the second set at a portion of support 3 connected to other drive beam 4B. Furthermore, other second wiring portion 39B has the one end electrically connected to the other end of second doped region 17 of the second set through plug 38C at the portion of support 3 connected to other drive beam 4B. Other second wiring portion 39B has the other end electrically connected to electrode pad 44b.

First doped region 16 and second doped region 17 of each set are electrically connected in parallel between first wiring portion 39A and second wiring portion 39B. First doped region 16 and second doped region 17 of the first set extending over drive beam 4A are electrically connected in parallel between the one end of first wiring portion 39A and the one end of one second wiring portion 39B. The first doped region 16 and the second doped region 17 of the second set extending over drive beam 4B are electrically connected in parallel between the other end of first wiring portion 39A and the one end of other second wiring portion 39B.

Each of first doped region 16 and second doped region 17 corresponds to a part of a first semiconductor layer 31 into which a dopant is introduced and diffused by any desired method. The method for diffusing the dopant is, for example, a method in which annealing is performed at a high temperature after ion implantation is performed using any desired mask pattern or a dopant paste is screen-printed, or a vapor-phase diffusion method using a silicon oxide film or a silicon nitride film as a mask. First wiring portion 39A and second wiring portion 39B are electrically connected only by first doped region 16 and second doped region 17 of each set.

First wiring portion 39A, second wiring portion 39B, and third wiring portion 39C are formed, for example, as first wiring 39 by the same process.

Electrode pads 44a and 44b are electrically connected to an external power supply (not illustrated). In optical scanning device 1, electrode pad 44a, one second wiring portion 39B, first doped region 16 and second doped region 17 of the first set, third wiring portion 39C, second wiring 37, first wiring portion 39A, first doped region 16 and second doped region 17 of the second set, other second wiring portion 39B, and electrode pad 44b are electrically connected in this order.

In plan view, the pair of magnets 6 are disposed such that reflector 2 and support 3 are interposed between the pair of magnets 6.

Reflector 2 is driven to twist (rotate) around each drive beam 4 by the Lorentz force produced by the action of a current flowing through first wiring portion 39A and lines of magnetic force of the pair of magnets 6.

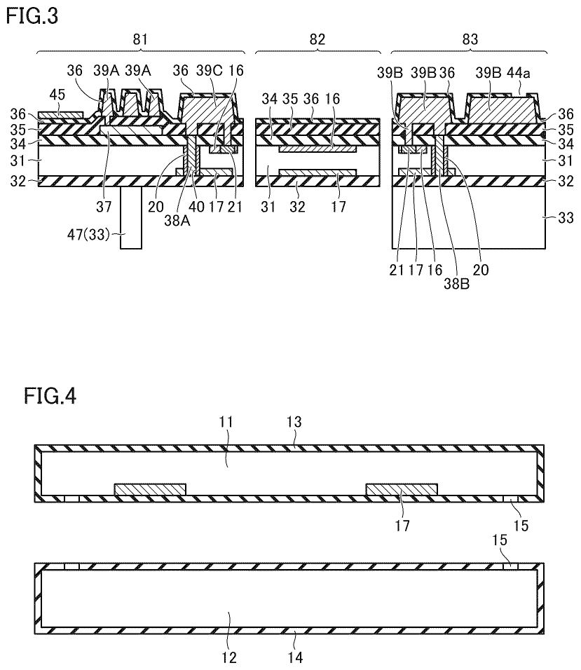

With reference to FIG. 3, a cross-sectional structure of optical scanning device 1 will be described next. In FIG. 3, a region 81 is a cross-sectional region of reflector 2 taken along a cross-sectional line IIIa-IIIa illustrated in FIG. 2, a region 82 is a cross-sectional region of drive beam 4 taken along a cross-sectional line IIIb-IIIb illustrated in FIG. 2, and a region 83 is a cross-sectional region of support 3 taken along a cross-sectional line IIIc-IIIc illustrated in FIG. 2.

As illustrated in FIG. 3, reflector 2, support 3, and each drive beam 4 each include a first insulating layer 34, first semiconductor layer 31 (active layer), and a second insulating layer 32 (buried oxide (BOX) layer) that are laminated in this order, first doped region 16, and second doped region 17. Hereinafter, a direction in which first insulating layer 34, first semiconductor layer 31, and second insulating layer 32 are laminated is simply referred to as a laminating direction.

As illustrated in FIG. 3, at least a part of reflector 2 and support 3 further includes a second semiconductor layer 33 (support layer). First semiconductor layer 31, second insulating layer 32, second semiconductor layer 33, first doped region 16, and second doped region 17 are formed of an SOI substrate 51 (see FIG. 4) to be described later. In other words, the entirety of reflector 2, support 3, and drive beams 4A and 4B, and a part of drive portion 5 are formed of the SOI substrate.

As illustrated in FIG. 3, in each of reflector 2, support 3, and each drive beam 4, first doped region 16 is formed at an interface between first insulating layer 34 and first semiconductor layer 31, and second doped region 17 is formed at an interface between first semiconductor layer 31 and second insulating layer 32. First doped region 16 is a region extending from a front surface of first semiconductor layer 31 toward a back surface in a direction perpendicular to the front surface (laminating direction). Second doped region 17 is a region extending from the back surface of first semiconductor layer 31 toward the front surface in a direction perpendicular to the back surface.

In plan view, the entirety of first doped region 16 is aligned with a part of second doped region 17, for example. A width of each of first doped region 16 and second doped region 17 in a direction (second direction) perpendicular to an extending direction (first direction) is greater than or equal to 50%, preferably 70% of a width of each drive beam 4 in the second direction.

Note that at least a part of first doped region 16 may be aligned with at least a part of second doped region 17 in plan view. A part of first doped region 16 may be aligned with the entirety of second doped region 17 in plan view.

First semiconductor layer 31 has, for example, a first conductivity type. First doped region 16 and second doped region 17 each have a second conductivity type different from the first conductivity type. Preferably, an impurity concentration of first doped region 16 and an impurity concentration of second doped region 17 are greater than or equal to 1*10⁸ atoms/cm³.

A lower limit value of a thickness of first semiconductor layer 31 and an upper limit value of a depth of each of first doped region 16 and second doped region 17 are set from the viewpoint of preventing punch-through between first doped region 16 and second doped region 17. A lower limit value of the depth of each of first doped region 16 and second doped region 17 is set from the viewpoint of sufficiently lowering a sheet resistance value of each of first doped region 16 and second doped region 17. The thickness of first semiconductor layer 31 is greater than or equal to 10 μm and less than or equal to 120 μm. Here, the thickness of first semiconductor layer 31 is a distance in the laminating direction between first doped region 16 and second doped region 17. The depth of each of first doped region 16 and second doped region 17 is greater than or equal to 1 μm and less than or equal to 2 μm, for example.

The depth of first doped region 16 is a distance between a position indicating an impurity concentration of 1/10 of the maximum impurity concentration in an impurity concentration profile in the direction perpendicular to the front surface of first semiconductor layer 31 and the front surface of first semiconductor layer 31. The depth of second doped region 17 is a distance between a position indicating an impurity concentration of 1/10 of the maximum impurity concentration in an impurity concentration profile in the direction perpendicular to the back surface of first semiconductor layer 31 and the back surface of first semiconductor layer 31.

As illustrated in FIG. 3, in region 81, second wiring 37, a third insulating layer 35, first wiring portion 39A of first wiring 39, third wiring portion 39C, fourth insulating layer 36, and reflection film 45 are formed on first insulating layer 34. In region 81, plug 38A is formed in first semiconductor layer 31 and first insulating layer 34.

As illustrated in FIG. 3, second wiring 37 is covered with third insulating layer 35. Second wiring 37 electrically connects the one end of first wiring portion 39A and the one end of each of first doped region 16 and second doped region 17 of the first set. Second wiring 37 is a so-called jumper wiring. In plan view, second wiring 37 includes a portion aligned with the one end of first wiring portion 39A, a portion aligned with the one end of each of first doped region 16 and second doped region 17 of the first set, and a portion extending between the portions and aligned with the other portion of first wiring portion 39A disposed outside the one end of first wiring portion 39A.

As illustrated in FIG. 3, first wiring portion 39A and third wiring portion 39C are formed on third insulating layer 35. The one end of first wiring portion 39A is formed so as to embed itself in a contact hole 43 (see FIG. 11) that extends to second wiring 37 through third insulating layer 35, and is electrically connected to second wiring 37. A part of third wiring portion 39C is formed so as to embed itself in a contact hole that extends to second wiring 37 through third insulating layer 35, and is electrically connected to second wiring 37. Another part of third wiring portion 39C is formed so as to embed itself in a contact hole 41 (see FIG. 11) that extends to first doped region 16 of the first set through third insulating layer 35 and first insulating layer 34, and is electrically connected to first doped region 16 of the first set. The other part of third wiring portion 39C: is formed so as to embed itself in a contact hole 42 (see FIG. 11) that extends to plug 38A through third insulating layer 35 and first insulating layer 34, and is electrically connected to second doped region 17 of the first set through plug 38A.

Plug 38A is formed so as to embed itself in a via hole 40 that extends through first semiconductor layer 31 and first insulating layer 34. Plug 38A is connected to a portion of second doped region 17 of the first set that is out of alignment with first doped region 16 in the laminating direction.

A part of the other end of first wiring portion 39A is formed so as to embed itself in contact hole 41 that extends to first doped region 16 of the second set through third insulating layer 35 and first insulating layer 34, and is electrically connected to first doped region 16 of the second set. The other part of the other end of first wiring portion 39A is formed so as to embed itself in contact hole 42 that extends to plug 3811 through third insulating layer 35 and first insulating layer 34, and is electrically connected to second doped region 17 of the second set through plug 3811.

Plug 38B is formed so as to embed itself in via hole 40 that extends through first semiconductor layer 31 and first insulating layer 34. Plug 38B is connected to a portion of second doped region 17 of the second set that is out of alignment with first doped region 16 in the laminating direction.

In region 81, fourth insulating layer 36 covers first wiring portion 39A. Reflection film 45 is formed on fourth insulating layer 36. In region 81, a rib 47 is formed on second insulating layer 32.

In region 82, third insulating layer 35 and fourth insulating layer 36 are formed on first insulating layer 34. In region 82, only first doped region 16 and second doped region 17 are formed as conductive layers, and no conductive layer is disposed on first insulating layer 34 and second insulating layer 32.

In region 83, third insulating layer 35, second wiring portion 39B of first wiring 39, electrode pads 44a and 44b, and fourth insulating layer 36 are formed on first insulating layer 34. Second wiring portion 393 is formed on third insulating layer 35. In region 83, plug 38C is formed in first semiconductor layer 31 and first insulating layer 34.

In region 83, a part of second wiring portion 39B is formed so as to embed itself in contact hole 41 that extends to first doped region 16 through third insulating layer 35 and first insulating layer 34, and is electrically connected to first doped region 16. The other part of second wiring portion 393 is formed so as to embed itself in contact hole 42 that extends to plug 38C through third insulating layer 35 and first insulating layer 34, and is electrically connected to second doped region 17 through plug 38C.

Plug 38C is formed so as to embed itself in via hole 40 that extends through first semiconductor layer 31 and first insulating layer 34. In plan view, plug 38C is connected to a portion of second doped region 17 that is out of alignment with first doped region 16.

In reflector 2 and support 3, a first contact region 20 is formed on an inner peripheral surface of a portion (second via hole) of each via hole 40 extending through first semiconductor layer 31 (inner peripheral surface of first semiconductor layer 31 exposed to via hole 40). First contact region 20 is a region extending from the inner peripheral surface of the via hole in a direction perpendicular to the inner peripheral surface (direction perpendicular to the laminating direction). First contact region 20 has the second conductivity type. First contact region 20 has a p-n junction with first semiconductor layer 31, thereby electrically isolating plug 38A or plug 38B from first semiconductor layer 31 (p-n junction isolation). First contact region 20 is electrically connected to second doped region 17. Preferably, a dopant contained in first contact region 20 is the same as a dopant contained in second doped region 17.

In plan view, a second contact region 21 is formed in a portion of first doped region 16 of the first set that is aligned with third wiring portion 39C and a portion of each of first doped regions 16 of the first set and the second set that is aligned with second wiring portion 39B. Second contact region 21 is a region extending from the front surface of first semiconductor layer 31 (interface between first semiconductor layer 31 and first insulating layer 34) in the direction perpendicular to the front surface. Second contact region 21 has the second conductivity type. Second contact region 21 is electrically connected to first doped region 16.

Each of first contact region 20 and second contact region 21 is a region of first semiconductor layer 31 into which a dopant is diffused by any desired method. The method for diffusing the dopant is, for example, a method in which annealing is performed at a high temperature after ion implantation is performed using any desired mask pattern or a dopant paste is screen-printed, or a vapor-phase diffusion method using, as a mask, first insulating layer 34 and third insulating layer 35 in each via hole is formed.

### <Method for Manufacturing Optical Scanning Device 1>

Next, an example of a method for manufacturing the optical scanning device 1 will be described. As illustrated in FIG. 4, first, a first silicon substrate 11 and a second silicon substrate 12 are prepared.

First silicon substrate 11 has the first conductivity type. Second doped region 17 having the second conductivity type is formed on a back surface of first silicon substrate 11. Second doped region 17 is formed by, for example, a method in which annealing is performed at a high temperature after ion implantation is performed using a resist mask or a dopant paste is screen-printed, or a vapor-phase diffusion method using, as a mask, first insulating layer 34 and third insulating layer 35 in which each via hole is formed. Preferably, the impurity concentration of second doped region 17 is greater than or equal to 1*10¹⁸ atoms/cm³. For example, the first conductivity type is an N-type, and the second conductivity type is a P-type. In this case, in second doped region 17, it is only required that any element being a P-type dopant be diffused into Si, and, for example, boron (B) is diffused. Note that the first conductivity type may be a P-type, and the second conductivity type may be an N-type.

A first bonding film 13 is formed all over first silicon substrate 11. A second bonding film 14 is formed all over second silicon substrate 12. First bonding film 13 and second bonding film 14 are, for example, silicon oxide films (SiO₂). An alignment mark 15 is formed in each of first bonding film 13 and second bonding film 14. Each alignment mark 15 is an alignment mark for use in relative alignment between first silicon substrate 11 with second silicon substrate 12 when first silicon substrate 11 and second silicon substrate 12 are bonded together in the next process. Alignment mark 15 formed in first bonding film 13 is formed as a trench in first bonding film 13 on the back surface of first silicon substrate 11, for example. Alignment mark 15 formed in second bonding film 14 is formed as a trench in second bonding film 14 on a front surface of second silicon substrate 12, for example. Note that each alignment mark 15 may be formed as a trench in first silicon substrate 11 or second silicon substrate 12.

Next, as illustrated in FIG. 5, first silicon substrate 11 and second silicon substrate 12 are bonded together with first bonding film 13 and second bonding film 14 interposed between first silicon substrate 11 and second silicon substrate 12.

Specifically, first, first silicon substrate 11 and second silicon substrate 12 are positioned such that the back surface of first silicon substrate 11 and the front surface of second silicon substrate 12 face each other, and alignment marks 15 are aligned with each other. Next, first bonding film 13 on the back surface of first silicon substrate 11 and second bonding film 14 on the front surface of second silicon substrate 12 are bonded together under pressure at room temperature. Next, the bonded body is heated in order to increase bonding strength. The heating temperature is higher than or equal to 600° C., for example. As a result, second insulating layer 32 is formed from first bonding film 13 and second bonding film 14.

Further, a part of the front surface side of first silicon substrate 11 is polished. As a result, first semiconductor layer 31 is formed from first silicon substrate 11, Second semiconductor layer 33 is formed from second silicon substrate 12. Note that a part of the back surface side of second silicon substrate 12 may be further polished.

The thickness of first semiconductor layer 31 is, as described above, greater than or equal to 10 μm and less than or equal to 120 μm, for example. A thickness of second semiconductor layer 33 may be selected as desired with handleability of SOI substrate 51 in the subsequent processes taken into consideration, and is greater than or equal to 300 μm and less than or equal to 750 μm, for example. A thickness of second insulating layer 32 is greater than or equal to 0.1 μm and less than or equal to 3.0 μm, for example.

Next, first doped region 16 is formed on the front surface side of first semiconductor layer 31. First doped region 16 is formed by, for example, a method in which ion implantation is performed using a resist mask or a dopant paste is screen-printed, or a vapor-phase diffusion method using, as a mask, first insulating layer 34 and third insulating layer 35 in which each via hole is formed. Thereafter, annealing for diffusing the dopant of each of first doped region 16 and second doped region 17 is performed. Conditions for the annealing are set so as to make the depth of each of first doped region 16 and second doped region 17 greater than or equal to 1 μm. The annealing is performed at a temperature greater than or equal to 800° C., for example.

First doped region 16 has the second conductivity type, as with second doped region 17. In first doped region 16, it is only required that any element being a P-type dopant be diffused into Si, and, for example, boron (B) is diffused.

Further, first insulating layer 34 is formed on the front surface of first semiconductor layer 31. A method for forming first insulating layer 34 is a thermal oxidation method. First insulating layer 34 is a thermal oxide film. A thickness of first insulating layer 34 is greater than or equal to 0.05 μm and less than or equal to 1.00 μm, for example.

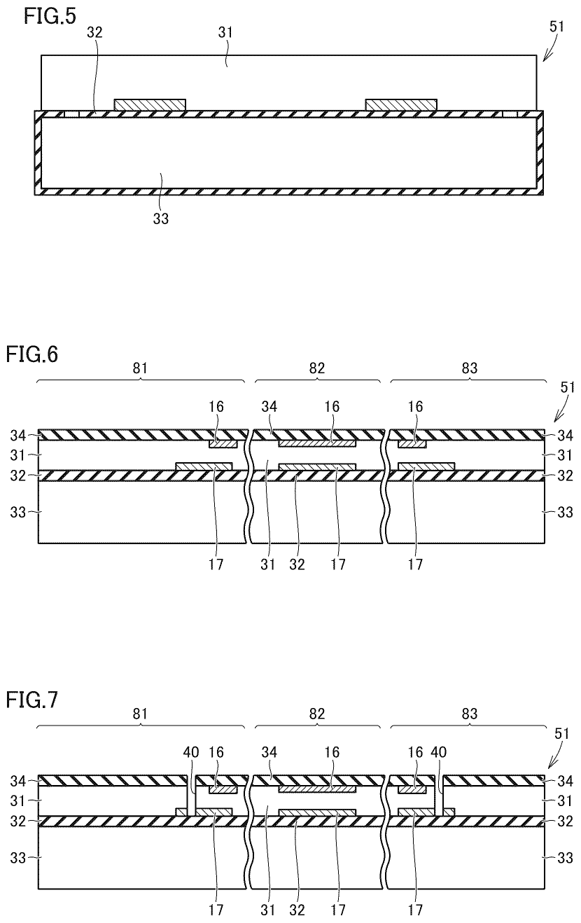

As a result, SOI substrate 51 illustrated in FIG. 6 is formed. SOI substrate 51 includes region 81 in which reflector 2 is to be formed, region 82 in which drive beam 4 is to be formed, and region 83 in which support 3 is to be formed.

Next, as illustrated in FIG. 7, the plurality of via holes 40 extending from first insulating layer 34 to second doped region 17 are formed. Each via hole 40 is a through hole in which a corresponding one of plugs 38A, 38B, and 38C is disposed. A method for forming via holes 40 is a dry etching method such as chemical dry etching, reactive ion etching, high density plasma etching, or deep reactive-ion etching (deep-RIE).

An etching mask used in etching of first insulating layer 34 is a resist mask, for example. The resist mask is formed by photolithography. An etching mask used in etching of first semiconductor layer 31 is a resist mask or first insulating layer 34, for example.

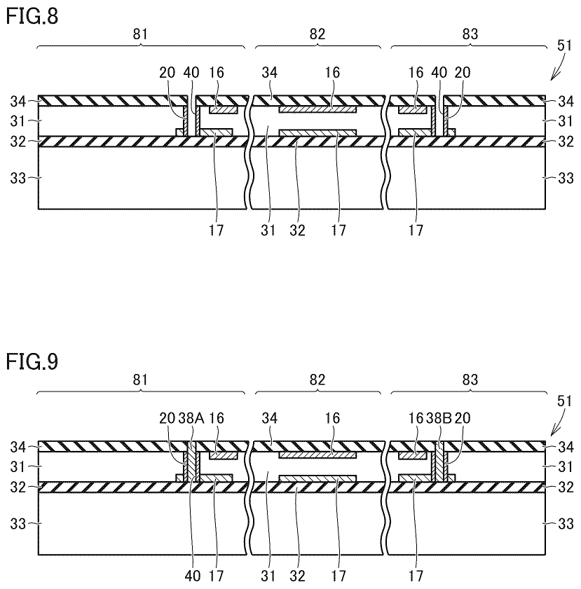

Next, as illustrated in FIG. 8, first contact region 20 is formed extending from the inner peripheral surface of the portion of each via hole 40 extending through first semiconductor layer 31 (the inner peripheral surface of first semiconductor layer 31 exposed to via hole 40) in the direction perpendicular to the inner peripheral surface. First contact region 20 has the second conductivity type. Preferably, a dopant contained in first contact region 20 is the same as a dopant contained in second doped region 17.

First contact region 20 is formed by, for example, a method in which annealing is performed at a high temperature after ion implantation is performed using, as a mask, first insulating layer 34 in which via hole 40 is formed or a dopant paste is screen-printed, or a vapor-phase diffusion method using, as a mask, first insulating layer 34 in which via hole 40 is formed.

Next, as illustrated in FIG. 9, plug 38A, plug 38B (not illustrated in FIG. 9), and plug 38C that each embed itself in a corresponding via hole 40 are formed. Specifically, first, a conductive material constituting plugs 38A, 38B, and 38C is deposited to embed itself in each via hole 40. Next, etching-back is performed by a dry etching process using first insulating layer 34 as a mask to planarize the conductive film to form plugs 38A, 38B, and 38C.

The material constituting plugs 38A, 38B, and 38C may be any conductive material, and includes, for example, at least one of titanium (Ti) or tungsten (W). Plugs 38A, 38B, and 38C are each a multilayer body in which a Ti layer, a titanium nitride (TiN) layer, and a W layer are laminated in this order, for example. The material constituting plugs 38A, 38B, and 38C may include, for example, polysilicon, A method for depositing the conductive material constituting plugs 38A, 38B, and 38C is, for example, a sputtering method or a chemical vapor deposition (CVD) method.

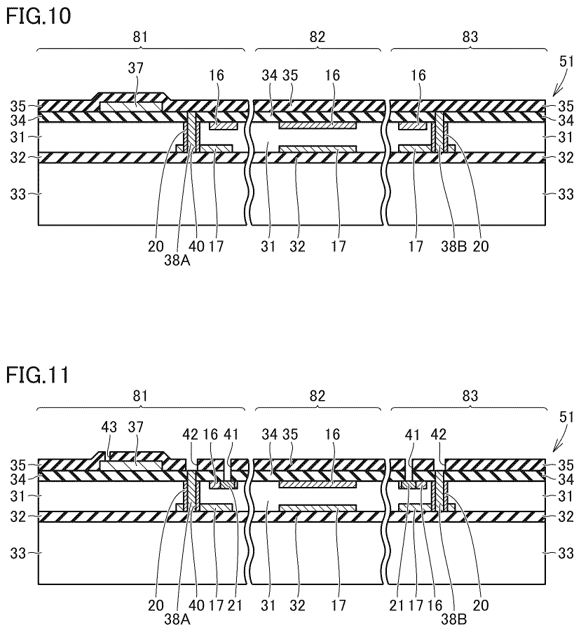

Next, as illustrated in FIG. 10, second wiring 37 is formed on first insulating layer 34. Third insulating layer 35 is further formed on first insulating layer 34, plugs 38A, 38B, and 38C, and second wiring 37. Specifically, a conductive material constituting second wiring 37 is deposited on first insulating layer 34 and plugs 38A, 38B, and 38C. Next, the film made of the conductive material is patterned by a dry etching process to form second wiring 37. Next, third insulating layer 35 is formed so as to cover second wiring 37.

The material constituting second wiring 37 may be any conductive material, and includes, for example, at least one of polysilicon or metal silicide. The polysilicon includes, for example, a high concentration of at least one of phosphorus (P) or boron (B). The metal silicide includes at least one selected from the group consisting of, for example, tungsten silicide (WSi2), molybdenum silicide (MoSi2), tantalum silicide (TaSi2), and titanium silicide (TiSi2). A thickness of second wiring 37 is, for example, greater than or equal to 0.1 μm and less than or equal to 5.0 μm and preferably greater than or equal to 0.1 μm and less than or equal to 1.0 μm.

A method for depositing the conductive material constituting second wiring 37 is, for example, a CVD method. The dry etching process may be selected as desired from the above-described dry etching methods, and is, for example, RIE. The etching mask used in the dry etching is, for example, a resist mask. The resist mask is formed by photolithography.

Third insulating layer 35 includes at least one selected from the group consisting of, for example, a silicon oxide film (SiO₂), a silicon oxide film doped with phosphorus (Phospho Silicate Glass: PSG), a silicon oxide film doped with boron (Boron Silicate Glass: BSG), a silicon oxide film doped with boron and phosphorus (Boron Phospho Silicate Glass: BPSG), a tetra ethoxy silane (TEOS) film, a spin on glass (SOG) film, and a silicon nitride film (Si₃N₄). A thickness of third insulating layer 35 is greater than or equal to 0.5 μm and less than or equal to 3.0 μm, for example.

A method for forming third insulating layer 35 is, for example, a sputtering method, a CVD method, or a coating method. The CVD method is a low pressure CVD method, an atmospheric pressure CVD method, or a plasma-enhanced CVD method.

Next, as illustrated in FIG. 11, contact hole 41 extending through third insulating layer 35 and first insulating layer 34 and contact holes 42 and 43 extending through third insulating layer 35 are formed. Further, second contact region 21 is formed in first doped region 16.

Each of contact holes 41, 42, and 43 is a through hole for electrically connecting first wiring portion 39A, second wiring portion 39B, or third wiring portion 39C to first doped region 16 or plugs 38A, 38B, and 38C. A method for forming contact holes 41, 42, and 43 may be selected as desired from the above-described dry etching methods, and is, for example, RIE.

An etching mask used in etching of third insulating layer 35 and first insulating layer 34 is, for example, a resist mask. The resist mask is formed by photolithography.

Second contact region 21 has the second conductivity type. Second contact region 21 is formed by, for example, a method in which annealing is performed at a high temperature after ion implantation is performed using, as a mask, first insulating layer 34 and third insulating layer 35 in which contact hole 42 is formed or a dopant paste is screen-printed, or a vapor-phase diffusion method using, as a mask, first insulating layer 34 and third insulating layer 35 in which contact hole 42 is formed.

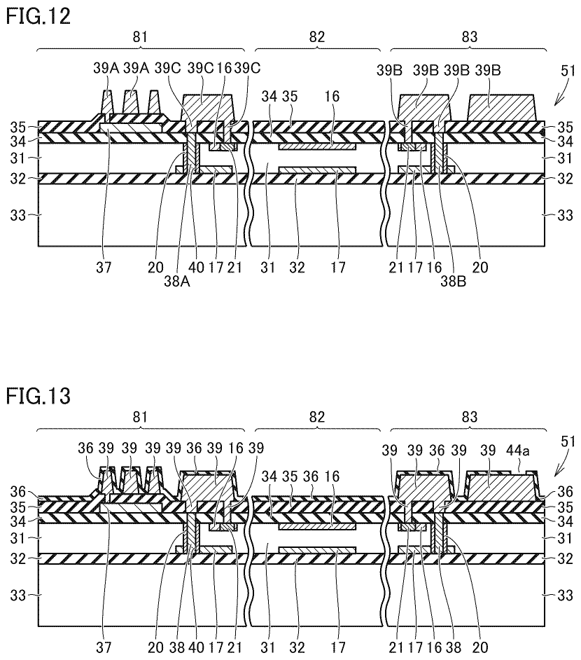

Next, as illustrated in FIG. 12, first wiring 39 is formed on third insulating layer 35. Specifically, first, a conductive material constituting first wiring 39 is deposited so as to embed itself in contact holes 41, 42, and 43. Next, the film made of the conductive material is patterned by a dry etching process or a wet etching process to form first wiring 39.

The material constituting first wiring 39 may be any conductive material, and includes, for example, at least one of Ti, aluminum (Al), or copper (Cu). First wiring 39 is, for example, a multilayer body in which a first layer made of a material high in adhesion to a base such as third insulating layer 35, second wiring 37, and second contact region 21, a second layer made of a material high in electrical conductivity, and a third layer made of a material high in corrosion resistance are laminated in this order. The first layer is, for example, a Ti layer, a titanium nitride (TiN) layer, or a multilayer body of the Ti layer and the TiN layer. The second layer is, for example, an Al layer, an Al silicide (AlSi) layer, an Al and Cu alloy (AlCu) layer, an aluminum nitride (AlN) layer, or a Cu layer, or a multilayer body of at least two layers selected from the group consisting of the Al layer, the AlSi layer, the AlCu layer, the AlN layer, and the Cu layer. The third layer is, for example, a Ti layer, a titanium nitride (TiN) layer, or a multilayer body of the Ti layer and the TiN layer.

A method for depositing the conductive material constituting first wiring 39 is, for example, a sputtering method or a plating method. The dry etching process may be selected as desired from the above-described dry etching methods, and is, for example, RIB In the wet etching process, an etchant solution selected according to the material constituting first wiring 39 is used. The etching mask used in the dry etching or the wet etching is, for example, a resist mask. The resist mask is formed by photolithography.

Next, as illustrated in FIG. 13, fourth insulating layer 36 is formed. Specifically, first, an insulating material constituting fourth insulating layer 36 is deposited so as to cover first wiring 39. Next, the film made of the insulating material is patterned by a dry etching process to form fourth insulating layer 36. Fourth insulating layer 36 includes at least one selected from the group consisting of, for example, a SiO₂ film, a PSG film, a BSG film, a BPSG film, a TEOS film, and a Si₃N₄ film, A thickness of fourth insulating layer 36 is greater than or equal to 0.05 μm and less than or equal to 1 μm, for example.

A method for forming fourth insulating layer 36 is, for example, a plasma-enhanced CVD method, a sputtering method, or a coating method. The dry etching process may be selected as desired from the above-described dry etching methods, and is, for example, RIE. The etching mask used in the dry etching is, for example, a resist mask. The resist mask is formed by photolithography.

As a result, drive portion 5 is formed on SOI substrate 51.

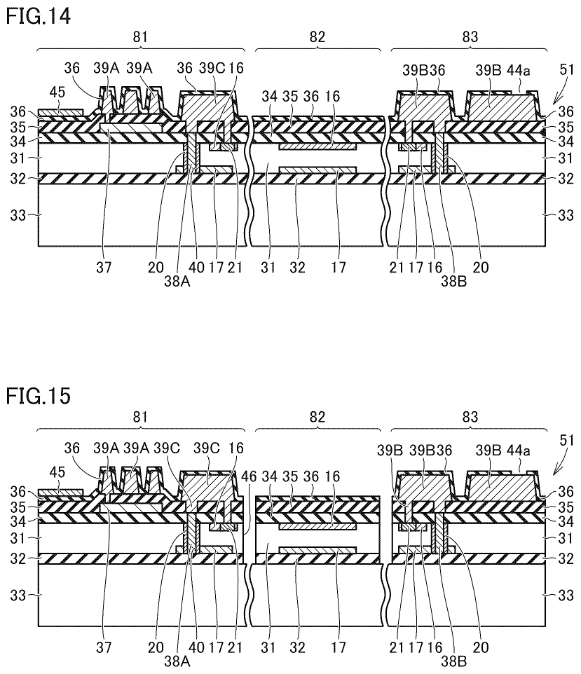

Next, as illustrated in FIG. 14, reflection film 45 is formed on fourth insulating layer 36 in region 81. Specifically, a material constituting reflection film 45 is deposited on fourth insulating layer 36. Next, the film made of the material constituting reflection film 45 is patterned by a dry etching process or a wet etching process to form reflection film 45.

The material constituting reflection film 45 includes a material high in reflectivity to scanned light. In a case where the scanned light is infrared light, the material constituting reflection film 45 includes gold (Au). Preferably, reflection film 45 is a multilayer body of an adhesion layer made of a material high in adhesion to fourth insulating layer 36 as a base and a reflection layer made of a material high in reflectivity to the scanned light. Reflection film 45 is, for example, a multilayer body in which a chromium (Cr) film, a nickel (Ni) film, and an Au film are laminated in this order, or a multilayer body in which a Ti film, a platinum (Pt) film, and an Au film are laminated in this order. A method for forming reflection film 45 is, for example, a sputtering method or a vacuum vapor deposition method.

The dry etching process may be selected as desired from the above-described dry etching methods, and is, for example, RIE. The etching mask used in the dry etching is, for example, a resist mask. The resist mask is formed by photolithography.

Next, as illustrated in FIG. 15, fourth insulating layer 36, third insulating layer 35, first insulating layer 34, first semiconductor layer 31, and second insulating layer 32 are patterned by a dry etching process. Specifically, after an etching mask is formed by photolithography, fourth insulating layer 36, third insulating layer 35, first insulating layer 34, first semiconductor layer 31, and second insulating layer 32 are sequentially subjected to the dry etching process. As a result, a part of second semiconductor layer 33 is also exposed to the front surface side.

The dry etching process may be selected as desired from the above-described dry etching methods. The dry etching process applied to first semiconductor layer 31 is a Deep-RIE method. A sidewall surface 46 is formed on first semiconductor layer 31 after being subjected to Deep-RIE. In a cross section along a thickness direction of first semiconductor layer 31, sidewall surface 46 has a scalloped shape. In order to planarize sidewall surface 46, sidewall surface 46 may be subjected to a CDE process before the dry etching process is performed on second insulating layer 32.

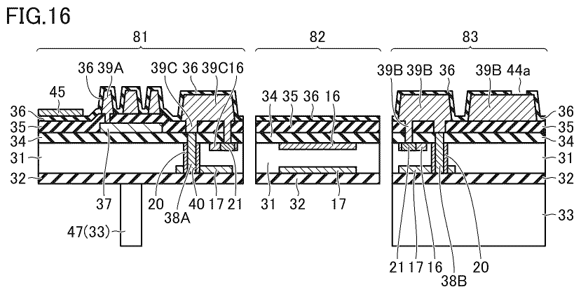

Next, as illustrated in FIG. 16, after an etching mask is formed by photolithography, second semiconductor layer 33 is patterned by a dry etching process. As a result, a structure including reflector 2, support 3, and the plurality of drive beams 4 is formed from SOI substrate 51.

The dry etching process applied to second semiconductor layer 33 is a Deep-RIE method. In order to increase rigidity of reflector 2, rib 47 is formed on second insulating layer 32 of reflector 2.

Note that a plurality of structures including reflector 2, support 3, and the plurality of drive beam 4 are formed on SOI substrate 51 and are connected via first semiconductor layer 31 remaining as a dicing line.

Further, in this process, processing of reducing the thickness of second semiconductor layer 33, such as processing of polishing the back surface of second semiconductor layer 33, may be further performed. The thickness of second semiconductor layer 33 in a process prior to this process is selected with handleability of SOI substrate 51 taken into consideration. The thickness of second semiconductor layer 33 after this process may be selected with drive characteristics of optical scanning device 1 taken into consideration, and is, for example, greater than or equal to 100 m and less than or equal to 300 μm.

Next, the structure including reflector 2, support 3, and the plurality of drive beams 4 is taken out as a chip from SOI substrate 51. Specifically, for example, when first semiconductor layer 31 is diced along the dicing line by stealth laser dicing or blade dicing, the structure including reflector 2, support 3, and drive beams 4 is taken out as optical scanning device 1. As described above, optical scanning device 1 illustrated in FIGS. 1 to 3 is manufactured.

### Actions and Effects

In an optical scanning device having a conductive layer formed on a drive beam, in a case where a reflector is driven at a relatively wide deflection angle, a relatively large stress is applied to the conductive layer, making the physical properties of the conductive layer likely to change (deteriorate). In particular, in a case where the reflector is continuously driven at a relatively wide deflection angle, a void (defect) due to stress-induced migration is formed in the conductive layer.

In optical scanning device 1, drive beams 4A and 4B include first doped region 16 formed at the interface between first insulating layer 34 and first semiconductor layer 31, and second doped region 17 formed at the interface between first semiconductor layer 31 and second insulating layer 32. First doped region 16 and second doped region 17 electrically connect first wiring portion 39A, third wiring portion 39C, and second wiring 37 as the first conductive portion, and second wiring portion 39B and electrode pads 44a and 44b as the second conductive portion.

Therefore, for optical scanning device 1, a conductive layer for electrically connecting the first conductive portion and the second conductive portion need not be provided on drive beams 4A and 4B. Even in a case where reflector 2 of optical scanning device 1 is driven at a relatively wide deflection angle, a change in physical properties of each of first doped region 16 and second doped region 17 extending over each of drive beams 4A and 4B can be suppressed as compared with a change in physical properties of a conductive layer in a case where a reflector of an optical scanning device having the conductive layer formed on a drive beam is similarly driven.

Furthermore, in optical scanning device 1, first doped region 16 and second doped region 17 are electrically connected in parallel between the first conductive portion and the second conductive portion. This makes a combined value of the sheet resistance values of first doped region 16 and second doped region 17 low as compared with the sheet resistance value of first doped region 16 in a case where only first doped region 16 electrically connects the first conductive portion and the second conductive portion, for example.

That is, in optical scanning device 1, first doped region 16 and second doped region 17 act as a wiring portion having a low sheet resistance value while suppressing a change in physical properties.

In particular, in optical scanning device 1, first doped region 16 and second doped region 17 are disposed in alignment with each other in the laminating direction.

In this case, the width of each of first doped region 16 and second doped region 17 in the second direction can be wide as compared with a case where first doped region 16 and second doped region 17 are disposed out of alignment with each other in the laminating direction. As a result, the combined value of the sheet resistance values of first doped region 16 and second doped region 17 of optical scanning device 1 can be reduced to less than or equal to the sheet resistance value of the conductive layer in the optical scanning device in which the conductive layer is formed on the drive beam.

Furthermore, in optical scanning device 1, since first doped region 16 and second doped region 17 are formed on different surfaces of SOI substrate 51, a degree of freedom in layout of first doped region 16 and second doped region 17 in plan view is improved as compared with a case where first doped region 16 and second doped region 17 are formed on the same surface of SOI substrate 51.

Optical scanning device 1 further includes first contact region 20 formed on the inner peripheral surface of via hole 40 as the first via hole or the second via hole. First contact region 20 has the second conductivity type, as with second doped region 17.

Therefore, first contact region 20 has a p-n junction with first semiconductor layer 31, thereby electrically isolating plug 38A or plug 38B from first semiconductor layer 31 (p-n junction isolation).

Furthermore, first contact region 20 is electrically connected to second doped region 17, Therefore, contact resistance between second doped region 17, and plugs 38A, 38B, and 38C and first contact region 20 is reduced as compared with a case where first contact region 20 is not provided.

In optical scanning device 1, the impurity concentration of each of first doped region 16 and second doped region 17 is greater than or equal to 1*10¹⁸ atoms/cm³. As described above, the combined value of the sheet resistance values of first doped region 16 and second doped region 17 becomes sufficiently low, and the amount of heat generated in first doped region 16 and second doped region 17 can be sufficiently reduced.

In optical scanning device 1, the thickness of first semiconductor layer 31 in the laminating direction is greater than or equal to 10 μm. This makes it possible to sufficiently reduce the possibility of punch-through between first doped region 16 and second doped region 17.

In optical scanning device 1, no conductive layer is disposed on first insulating layer 34 and second insulating layer 32 of drive beams 4A and 4B. Therefore, in optical scanning device 1, as compared with a case where a conductive layer is formed on drive beams 4A and 4B in addition to first doped region 16 and second doped region 17, a change in drive characteristics of reflector 2 due to a change in physical properties of the conductive layer is suppressed.

### Modification

In optical scanning device 1 of the first embodiment, first doped region 16 is formed at the interface between first semiconductor layer 31 and first insulating layer 34, and second doped region 17 is formed at the interface between first semiconductor layer 31 and second insulating layer 32, but the present disclosure is not limited to such a configuration. First doped region 16 may be formed at any one of the interface between first insulating layer 34 and first semiconductor layer 31, the interface between first semiconductor layer 31 and second insulating layer 32, or the interface between second insulating layer 32 and second semiconductor layer 33. Second doped region 17 may be formed at any one of the interface between first insulating layer 34 and first semiconductor layer 31, the interface between first semiconductor layer 31 and second insulating layer 32, or the interface between second insulating layer 32 and second semiconductor layer 33, other than the interface where first doped region 16 is formed.

Optical scanning device 1 according to the first embodiment may further include a third doped region formed at the interface between second insulating layer 32 and second semiconductor layer 33, and disposed in alignment with first doped region 16 and second doped region 17 in the laminating direction. First doped region 16, second doped region 17, and the third doped region are electrically connected in parallel between the first conductive portion and the second conductive portion. In such an optical scanning device, the first conductive portion and the second conductive portion are connected with lower resistance as compared with optical scanning device 1.

### Second Embodiment

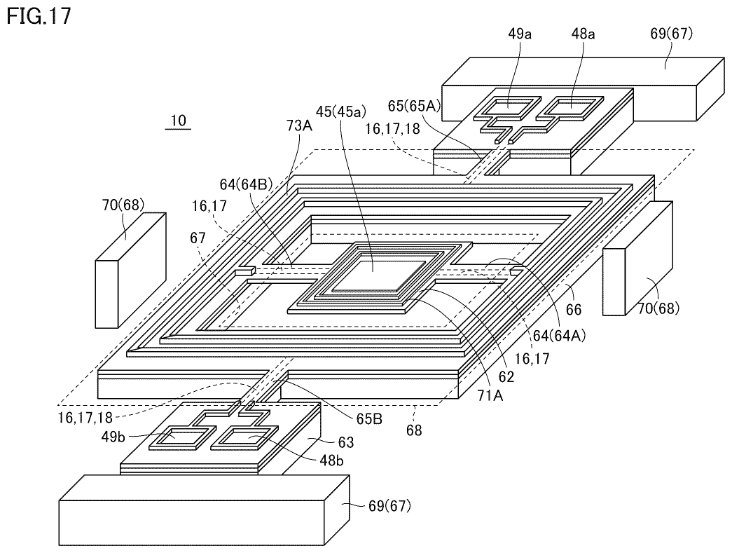

As illustrated in FIGS. 17 to 19, an optical scanning device 10 according to a second embodiment is basically identical in configuration to optical scanning device 1 according to the first embodiment, and produces the same effect as produced by optical scanning device 1 according to the first embodiment, but optical scanning device 10 is different from optical scanning device 1 in that optical scanning device 10 includes a reflector 62 that is driven around two axes. Optical scanning device 10 includes a first support 66 and a second support 63 as a support, a plurality of (for example, two) first drive beams 64 and a plurality of (for example, two) second drive beams 65 as a drive beam, and further includes a first drive portion 67 and a second drive portion 68 as a drive portion.

Optical scanning device 10 includes a plurality (for example, four sets) of first doped regions 16 and second doped regions 17, and a plurality (for example, two sets) of third doped regions 18. The plurality of first doped regions 16 and second doped regions 17 include a first set of first doped region 16 and second doped region 17 disposed in reflector 62, first support 66, and first drive beam 64A, a second set of first doped region 16 and second doped region 17 disposed in reflector 62, first support 66, and first drive beam 64B, a third set of first doped region 16 and second doped region 17 disposed in first support 66, second support 63, and second drive beam 65A, and a fourth set of first doped region 16 and second doped region 17 disposed in first support 66, second support 63, and second drive beam 65B. The plurality of third doped regions 18 include a third doped region 18 disposed in first support 66, second support 63, and second drive beam 65A, and a third doped region 18 disposed in first support 66, second support 63, and second drive beam 65B.

In plan view, each third doped region 18 is linearly disposed along the first direction. Third doped region 18 of each set has one end in the first direction disposed in first support 66. Third doped region 18 of each set has the other end in the first direction disposed in second support 63.

In plan view, a part of third doped region 18 is disposed in alignment with the entirety of first doped region 16 and second doped region 17. Note that, optical scanning device 10 is identical in configurations of first doped region 16 and second doped region 17 to optical scanning device 1, and thus no description will be given below of the configurations.

In plan view, first support 66 and second support 63 are disposed so as to surround reflector 62. In plan view, second support 63 is disposed outside first support 66. Second wiring portion 39B is disposed in second support 63.

Each of first drive beams 64A and 64B connects reflector 62 and first support 66. Each of second drive beams 65 and 65B connects first support 66 and second support 63. In plan view, first drive beams 64A and 64B are disposed such that reflector 62 is interposed between first drive beams 64A and 64B in the second direction. In plan view, second drive beams 65A and 65B are disposed such that reflector 62 is interposed between second drive beams 65A and 65B in the first direction orthogonal to the second direction. Each of first drive beams 64A and 64B has one end in the second direction connected to reflector 62. Each of first drive beams 64A and 64B has the other end in the first direction connected to first support 66. Each of second drive beams 65A and 65B has one end in the first direction connected to first support 66. Each of second drive beams 65A and 65B has the other end in the first direction connected to second support 63.

First drive portion 67 and the second drive portion 68 are, for example, drive portions of an electromagnetic drive type. First drive portion 67 drives reflector 62 to twist reflector 62 relative to first support 66 around first drive beams 64A and 64B. Second drive portion 68 drives reflector 62, first drive beams 64A and 64B, and first support 66 to twist reflector 62, first drive beams 64A and 64B, and first support 66 together relative to second support 63 around second drive beams 65A and 65B.

First drive portion 67 includes a fourth wiring portion 71A, a fifth wiring portion 72A, and a sixth wiring portion 71B as the first conductive portion disposed in reflector 62, seventh wiring portions 71C1 and 71C2 and electrode pads 48a and 48b as the second conductive portion disposed in second support 63, first doped region 16 and second doped region 17 extending over each of first drive beams 64A and 64B, third doped region 18 extending over each of second drive beams 65A and 65B, eighth wiring portions 71D1 and 71D2, ninth wiring portions 71E1 and 71E2, and tenth wiring portions 72111 and 72132 disposed in first support 66, and a pair of magnets 69.

For first drive portion 67, electrode pad 48a, seventh wiring portion 71C1, third doped region 18 disposed in second drive beam 65A, ninth wiring portion 71E, tenth wiring portion 72B1, eighth wiring portion 71D1, first doped region 16 and second doped region 17 disposed in second drive beam 65A, sixth wiring portion 71B, fifth wiring portion 72A, and one end of fourth wiring portion 71A are electrically connected in this order. Furthermore, tor first drive portion 67, the other end of fourth wiring portion 71A, first doped region 16 and second doped region 17 disposed in second drive beam 651, eighth wiring portion 71D2, tenth wiring portion 72132, ninth wiring portion 71E2, third doped region 18 disposed in second drive beam 65B, seventh wiring portion 71C2, and electrode pad 48b are electrically connected in this order.

First doped region 16 and second doped region 17 disposed in first drive beam 64A are electrically connected in parallel between eighth wiring portion 71D 1 and sixth wiring portion 71B. First doped region 16 and second doped region 17 disposed in first drive beam 64B are electrically connected in parallel between the other end of fourth wiring portion 71A and eighth wiring portion 71D2.

Eighth wiring portion 71D1 and sixth wiring portion 71B are electrically connected through only first doped region 16 and second doped region 17 disposed in first drive beam 64A. The other end of fourth wiring portion 71A and eighth wiring portion 71D2 are electrically connected through only first doped region 16 and second doped region 17 disposed in first drive beam 64B.

Second drive portion 68 includes an eleventh wiring portion 73A, a twelfth wiring portion 74, and a thirteenth wiring portion 73B as a third conductive portion disposed in first support 66, a fourteenth wiring portions 73C1 and 73C2 and electrode pads 49a and 49b as a fourth conductive portion disposed in second support 63, first doped region 16 and second doped region 17 extending over each of second drive beams 65A and 65B, and the pair of magnets 69.

For second drive portion 68, electrode pad 49a, fourteenth wiring portion 73C1, first doped region 16 and second doped region 17 disposed in second drive beam 65A, eleventh wiring portion 73A, twelfth wiring portion 74, thirteenth wiring portion 73B, first doped region 16 and second doped region 17 disposed in second drive beam 65B, fourteenth wiring portion 73C2, and electrode pad 49b are electrically connected in this order.

Electrode pads 48a and 48B are electrically connected to a first external power supply (not illustrated). Electrode pads 49a and 49B are electrically connected to a second external power supply (not illustrated) different from the first external power supply.

First doped region 16 and second doped region 17 disposed in second drive beam 65A are electrically connected in parallel between one end of fourteenth wiring portion 73C1 and eleventh wiring portion 73A. First doped region 16 and second doped region 17 disposed in second drive beam 65B are electrically connected in parallel between thirteenth wiring portion 73B and fourteenth wiring portion 73C2. First doped region 16 and second doped region 17 disposed in each of second drive beams 65A and 65B are electrically isolated from third doped region 18 disposed in each of second drive beams 65A and 65B. The configuration where first doped region 16 and second doped region 17, and third doped region 18 are electrically isolated from each other means that first doped region 16 and second doped region 17, and third doped region 18 are disposed such that different potentials are applied to first doped region 16 and second doped region 17, and third doped region 18.

Fourteenth wiring portion 73C1 and the one end of eleventh wiring portion 73A are electrically connected through only first doped region 16 and second doped region 17 disposed in second drive beam 65A. Thirteenth wiring portion 73B and fourteenth wiring portion 73C2 are electrically connected through only first doped region 16 and second doped region 17 disposed in second drive beam 65B.

Fourth wiring portion 71A, sixth wiring portion 71B, seventh wiring portions 71C1 and 71C2, eighth wiring portions 71D1 and 71D2, and ninth wiring portions 71E1 and 71E2 are formed by, for example, the same process. Fourth wiring portion 71A, sixth wiring portion 71B, seventh wiring portions 71C 1 and 71C2, eighth wiring portions 71D1 and 71D2, and ninth wiring portions 71E1 and 71E2 are collectively referred to as a third wiring 71. Third wiring 71 is disposed on third insulating layer 35.

Fifth wiring portion 72A and tenth wiring portions 72111 and 72112 are formed by, for example, the same process. Fifth wiring portion 72A and tenth wiring portions 72B1 and 72B2 are collectively referred to as a fourth wiring 72. Fourth wiring 72 is disposed on first insulating layer 34 and covered with third insulating layer 35.

Eleventh wiring portion 73A, thirteenth wiring portion 73B, and fourteenth wiring portion 73C 1 and 73C2 are formed by, for example, the same process. Eleventh wiring portion 73A, thirteenth wiring portion 73B, and fourteenth wiring portions 73C1 and 73C2 are collectively referred to as a fifth wiring 73. Fifth wiring 73 is disposed on third insulating layer 35. Twelfth wiring portion 74 is disposed on first insulating layer 34 and covered with third insulating layer 35.

Second drive portion 68 is basically identical in configuration to drive portion 5 of optical scanning device 1. A connection structure between fifth wiring 73, twelfth wiring portion 74, the two sets of first doped regions 16 and second doped regions 17 is identical in configuration to the connection structure between first wiring 39, second wiring 37, the two sets of first doped regions 16 and second doped regions 17 of optical scanning device 1.

First drive portion 67 is basically identical in configuration to drive portion 5 of optical scanning device 1, but is different from drive portion 5 in the following points. Third wiring 71 is basically identical in configuration to first wiring 39 of optical scanning device 1, but is different from first wiring 39 in the following points. Fourth wiring 72 is basically identical in configuration to second wiring 37 of optical scanning device 1, but is different from second wiring 37 in the following points.

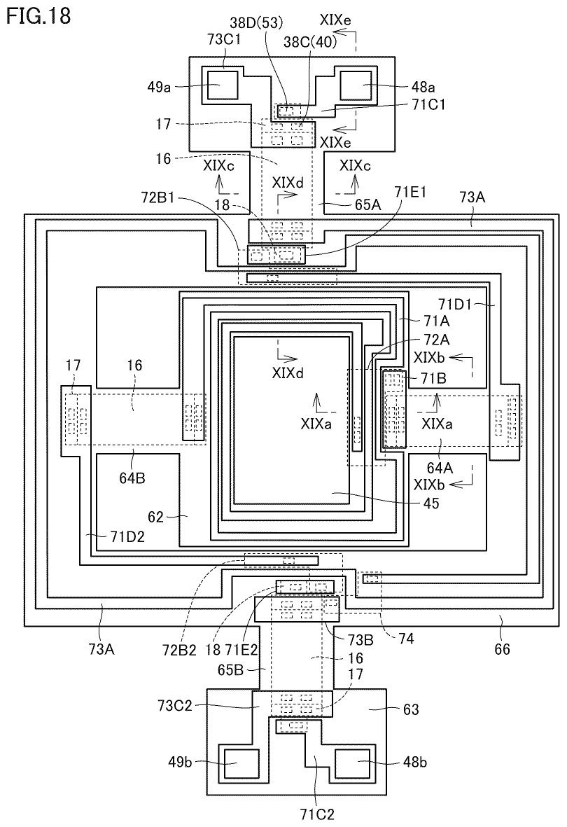

As illustrated in FIG. 18, fourth wiring portion 71A has the one end electrically connected to the one end of first doped region 16 disposed in first drive beam 64A through fifth wiring portion 72A and sixth wiring portion 71B at a portion of reflector 62 connected to first drive beam 64A. Furthermore, fourth wiring portion 71A has the one end electrically connected to the one end of second doped region 17 disposed in first drive beam 64A through fifth wiring portion 72A, sixth wiring portion 71B, and plug 38A at the portion of reflector 62 connected to first drive beam 64A.

As illustrated in FIG. 18, fourth wiring portion 71A has the other end electrically connected to the one end of first doped region 16 extending over first drive beam 64B at a portion of reflector 62 connected to first drive beam 64B. Furthermore, fourth wiring portion 71A has the other end electrically connected to the one end of second doped region 17 extending over first drive beam 64B through plug 38B at the portion of reflector 62 connected to first drive beam 64B.

In plan view, first doped region 16 and second doped region 17 extending over each of first drive beams 64A and 64B are linearly disposed along the first direction. In plan view, first doped region 16 and second doped region 17 extending over each of second drive beams 65A and 65B are linearly disposed along the second direction.

As illustrated in FIG. 18, eighth wiring portion 71D1 has one end electrically connected to the other end of first doped region 16 extending over first drive beam 64A at a portion of first support 66 connected to first drive beam 64A. Furthermore, eighth wiring portion 71D1 has the one end electrically connected to the other end of second doped region 17 extending over first drive beam 64A through plug 38C at the portion of first support 66 connected to first drive beam 64A.

As illustrated in FIG. 18, eighth wiring portion 71D1 has the other end electrically connected to tenth wiring portion 72B1, ninth, wiring portion 71E1, and the one end of third doped region 18 extending over second drive beam 65A through plug 38D.

As illustrated in FIG. 18, eighth wiring portion 71D2 has one end electrically connected to the other end of first doped region 16 extending over first drive beam 64B at a portion of first support 66 connected to first drive beam 64B. Furthermore, eighth wiring portion 71D2 has the one end electrically connected to the other end of second doped region 17 extending over first drive beam 64B through plug 38C at the portion of first support 66 connected to first drive beam 64B.

As illustrated in FIG. 18, eighth wiring portion 71D2 has the other end electrically connected to tenth wiring portion 72B2, ninth wiring portion 71E2, and the one end of third doped region 18 extending over second drive beam 65B through plug 38D.

As illustrated in FIG. 18, seventh wiring portion 71C1 has one end electrically connected to the other end of third doped region 18 extending over second drive beam 65A through plug 38D at a portion of support 3 connected to second drive beam 65A. Seventh wiring portion 71C1 has the other end electrically connected to electrode pad 48a.

As illustrated in FIG. 18, seventh wiring portion 71C2 has one end electrically connected to the other end of third doped region 18 extending over second drive beam 65B through plug 38D at a portion of support 3 connected to second drive beam 65B. Seventh Wiring portion 71C2 has the other end electrically connected to electrode pad 48b.

Third doped region 18 is a region corresponding to a part of second semiconductor layer 33 into which a dopant is introduced and diffused by any desired method.

The pair of magnets 69 are disposed to face each other in the first direction. A pair of magnets 70 are disposed to face each other in the second direction.

Reflector 62 is driven to twist (rotate) around each of first drive beams 64A and 64B by the Lorentz force produced by the action of a current flowing through fourth wiring portion 71A and lines of magnetic force of the pair of magnets 69 and is further driven to twist (rotate) around each of second drive beams 65A and 65B by the Lorentz force produced by the action of a current flowing through eleventh wiring portion 73A and lines of magnetic force of the pair of magnets 70.

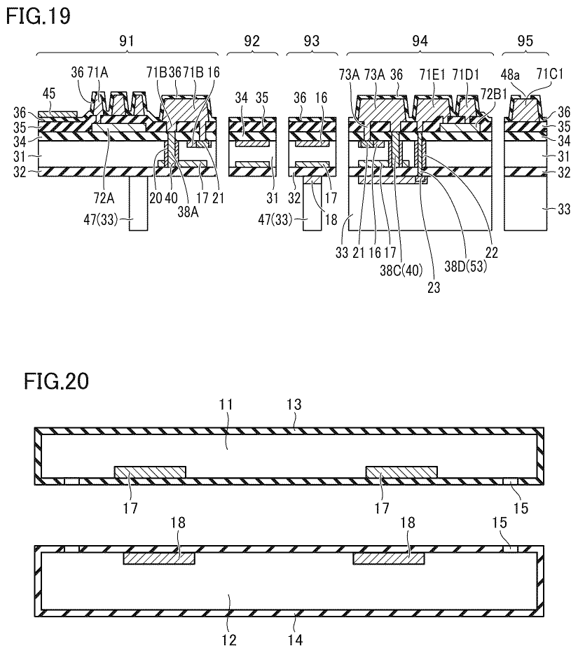

With reference to FIG. 19, a cross-sectional structure of optical scanning device 1 will be described next. In FIG. 19, a region 91 is a cross-sectional region of reflector 62 taken along a cross-sectional line XIXa-XIXa illustrated in FIG. 18, a region 92 is a cross-sectional region of first drive beam 64A taken along a cross-sectional line XIXb-XIXb illustrated in FIG. 18, a region 93 is a cross-sectional region of second drive beam 65A taken along a cross-sectional line XIXc-XIXc illustrated in FIG. 18, a region 94 is a cross-sectional region of first support 66 taken along a cross-sectional line XIXd-XIXd illustrated in FIG. 18, and a region 95 is a cross-sectional region of second support 63 taken along a cross-sectional line XIXe-XIXe illustrated in FIG. 18.

As illustrated in FIG. 19, reflector 62, first support 66, second support 63, first drive beams 64A and 64B, and second drive beams 65A and 65B each include first insulating layer 34, first semiconductor layer 31 (active layer), and second insulating layer 32 (buried oxide (BOX) layer) that are laminated in this order, first doped region 16, and second doped region 17.

First support 66, second support 63, and each of second drive beams 65A and 65B further include second semiconductor layer 33 (support layer) and third doped region 18. Reflector 62 and each of first drive beams 64A and 64B include no third doped region 18.

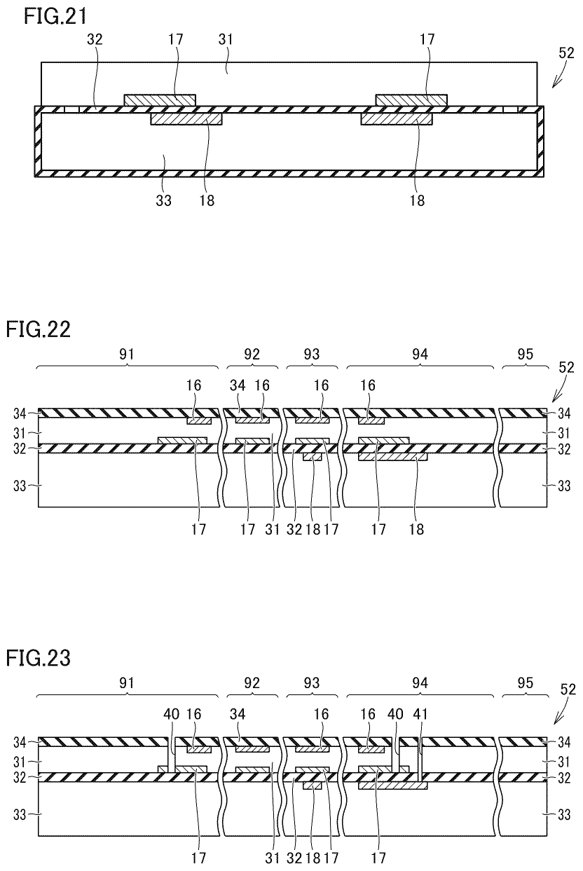

First semiconductor layer 31, second insulating layer 32, second semiconductor layer 33, first doped region 16, second doped region 17, and third doped region 18 are formed of an SOI substrate 51 (see FIG. 21) to be described later. In other words, reflector 62, first support 66, second support 63, each of first drive beams 64A and 64B, each of second drive beams 65A and 65B, a part of first drive portion 67, and a part of second drive portion 68 are formed of the SOT substrate.

As illustrated in FIG. 19, in each of reflector 62, first support 66, second support 63, first drive beams 64A and 64B, and second drive beams 65A and 65B, first doped region 16 is formed at the interface between first insulating layer 34 and first semiconductor layer 31, and second doped region 17 is formed at the interface between first semiconductor layer 31 and second insulating layer 32.

As illustrated in FIG. 19, in each of first support 66, second support 63, and second drive beams 65A and 65B, third doped region 18 is formed at the interface between second insulating layer 32 and second semiconductor layer 33.

Third doped region 18 is a region extending from the front surface of second semiconductor layer 33 toward the back surface in a direction perpendicular to the front surface.

In plan view, the entirety of first doped region 16 and the entirety of second doped region 17 are each disposed in alignment with a part of third doped region 18. Note that, in plan view, at least a part of first doped region 16 may be disposed in alignment with at least a part of third doped region 18.

First semiconductor layer 31 and second semiconductor layer 33 have, for example, the first conductivity type. First doped region 16, second doped region 17, and third doped region 18 each have the second conductivity type different from the first conductivity type. Preferably, an impurity concentration of each of first doped region 16, second doped region 17, and third doped region 18 is greater than or equal to 1*10¹⁸ atoms/cm³.

As illustrated in FIG. 19, regions 91 and 92 is identical in configuration to regions 81 and 92 of optical scanning device 1 illustrated in FIG. 3. Fourth wiring portion 71A and sixth wiring portion 71B are formed on third insulating layer 35 and covered with fourth insulating layer 36. Fifth wiring portion 72A is formed on first insulating layer 34 and covered with third insulating layer 35.

In region 93, second semiconductor layer 33 and third doped region 18 are formed on second insulating layer 32. In region 93, only first doped region 16, second doped region 17, and third doped region 18 are formed as a conductive layer, and no conductive layer is disposed on first insulating layer 34 and second semiconductor layer 33.

In region 94, third insulating layer 35, eleventh wiring portion 73A, ninth wiring portion 71E1, eighth wiring portion 71D1, and fourth insulating layer 36 are formed on first insulating layer 34. In region 94, plug 38D is formed in first semiconductor layer 31, first insulating layer 34, and second insulating layer 32.

In region 94, a part of ninth wiring portion 71E1 is formed so as to embed itself in a contact hole 53 that extends through third insulating layer 35 and first insulating layer 34 to plug 38D, and is electrically connected to second doped region 17 through plug 38C.

Plug 38D is formed so as to embed itself in a via hole 53 extending through first semiconductor layer 31, first insulating layer 34 and second insulating layer 32. In plan view, plug 38D is connected to a portion of third doped region 18 that is out of alignment with both first doped region 16 and second doped region 17.

In reflector 62 and support 3, a third contact region 22 is formed on an inner peripheral surface of a portion of each via hole 53 extending through first semiconductor layer 31. Third contact region 22 is basically identical in configuration to first contact region 20. Third contact region 22 is a region extending from the inner peripheral surface of the via hole in a direction perpendicular to the inner peripheral surface. Third contact region 22 has the second conductivity type. Third contact region 22 has a p-n junction with first semiconductor layer 31, thereby electrically isolating plug 38D from first semiconductor layer 31 (p-n junction isolation). Third contact region 22 is electrically connected to third doped region 18.

In plan view, a fourth contact region 23 is formed at a portion of third doped region 18 connected to plug 38D. Fourth contact region 23 is basically identical in configuration to second contact region 21. Fourth contact region 23 is a region extending from the front surface of second semiconductor layer 33 (interface between second semiconductor layer 33 and second insulating layer 32) in a direction perpendicular to the front surface. Fourth contact region 23 has the second conductivity type. Fourth contact region 23 is electrically connected to third doped region 18,

### <Method for Manufacturing Optical Scanning Device 10>

Next, an example of a method for manufacturing optical scanning device 10 will be described. Hereinafter, only differences from the method for manufacturing optical scanning device 1 will be described for the method for manufacturing optical scanning device 10.

As illustrated in FIG. 20, first, first silicon substrate 11 and second silicon substrate 12 are prepared. Second silicon substrate 12 has the first conductivity type. Third doped region 18 having the second conductivity type is formed on the front surface of second silicon substrate 12. Third doped region 18 is formed by, for example, a method in which ion implantation is performed using a resist mask or a dopant paste is screen-printed, or a vapor-phase diffusion method using, as a mask, first insulating layer 34 and third insulating layer 35 in which each via hole is formed. Preferably, the impurity concentration of third doped region 18 is greater than or equal to 1*10¹⁸ atoms/cm³. For example, the first conductivity type is an N-type, and the second conductivity type is a P-type. In this case, in third doped region 18, it is only required that any element being a P-type dopant be diffused into Si, and, for example, boron (B) is diffused. Note that the first conductivity type may be a P-type, and the second conductivity type may be an N-type.

Next, as illustrated in FIG. 21, first silicon substrate 11 and second silicon substrate 12 are bonded together with first bonding film 13 and second bonding film 14 interposed between first silicon substrate 11 and second silicon substrate 12. Further, a part of the front surface side of first silicon substrate 11 is polished. As a result, first semiconductor layer 31 is formed from first silicon substrate 11. Second semiconductor layer 33 is formed from second silicon substrate 12.

Next, as illustrated in FIG. 22, first doped region 16 is formed on the front surface side of first semiconductor layer 31. Further, first insulating layer 34 is formed on the front surface of first semiconductor layer 31.

As a result, an SOI substrate 52 illustrated in FIG. 22 is formed. SOI substrate 52 includes region 91 in which reflector 62 is to be formed, region 92 in which first drive beam 64A is to be formed, region 93 in which second drive beam 65A is to be formed, region 94 in which first support 66 is to be formed, and region 95 in which second support 63 is to be formed.

Next, as illustrated in FIG. 23, the plurality of via holes 40 extending from first insulating layer 34 to second doped region 17 and the plurality of via holes 53 extending from first insulating layer 34 to third doped region 18 are formed. Each via hole 40 and each via hole 53 are simultaneously formed by, for example, one etching process. Each via hole 40 is a through hole in which a corresponding one of plugs 38A, 38B, and 38C is disposed, and each via hole 53 is a through hole in which plug 38D is disposed.

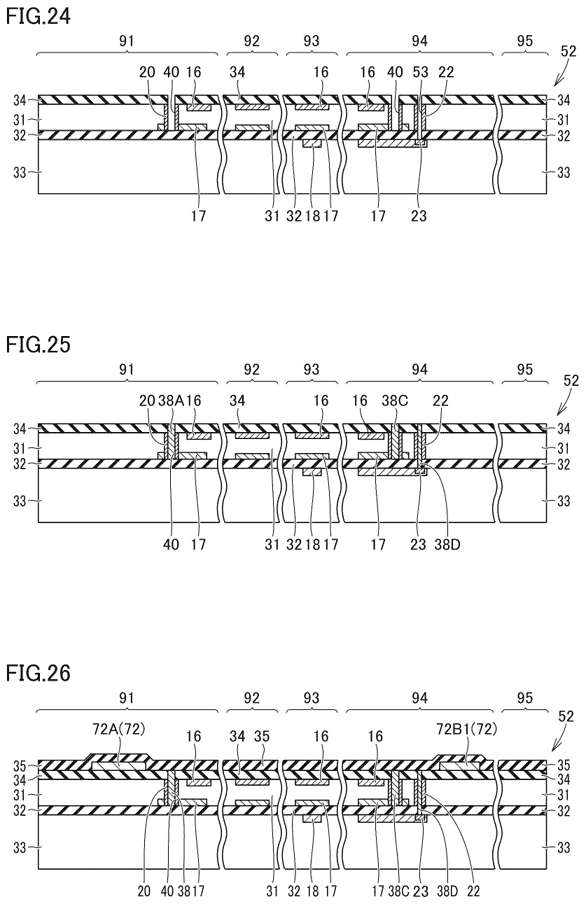

Next, as illustrated in FIG. 24, first contact region 20, third contact region 22, and fourth contact region 23 are formed. First contact region 20, third contact region 22, and fourth contact region 23 are simultaneously formed by, for example, one introduction/diffusion process.

Next, as illustrated in FIG. 25, plug 38A, plug 38B (not illustrated in FIG. 25), and plug 38C that each embed itself in a corresponding via hole 40, and plug 38D that embeds itself in each via hole 53 are formed. Plugs 38A, 38B, 38C, and 38D are simultaneously formed by, for example, one deposition process and one dry etching process.

A material constituting plug 38D may be any conductive material, and includes, for example, at least one of titanium (Ti) or tungsten (W), Plug 38D is, for example, a multilayer body in which a Ti layer, a titanium nitride (TiN) layer, and a W layer are laminated in this order, as with plugs 38A, 38B, and 38C. The material constituting plug 38D may include, for example, polysilicon.

Next, as illustrated in FIG. 26, fourth wiring 72 and twelfth wiring portion 74 (not illustrated in FIG. 26) are formed on first insulating layer 34. Further, third insulating layer 35 is formed on first insulating layer 34, plugs 38A, 38B, 38C, and 38D, fourth wiring 72, and twelfth wiring portion 74. Specifically, a conductive material constituting fourth wiring 72 and twelfth wiring portion 74 is deposited on first insulating layer 34 and plugs 38A, 38B, 38C, and 38D. Next, the film made of the conductive material is patterned by a dry etching process to form fourth wiring 72 and twelfth wiring portion 74. Next, third insulating layer 35 is formed so as to cover fourth wiring 72 and twelfth wiring portion 74.

Fourth wiring 72 and twelfth wiring portion 74 can be formed in the same manner as second wiring 37 of optical scanning device 1. The material constituting fourth wiring 72 and twelfth wiring portion 74 may be any conductive material, and includes, for example, at least one of polysilicon or metal silicide. The polysilicon includes, for example, a high concentration of at least one of phosphorus (P) or boron (B), The metal silicide includes at least one selected from the group consisting of, for example, tungsten silicide (WSi2), molybdenum silicide (MoSi2), tantalum silicide (TaSi2), and titanium silicide (TiSi2). A thickness of fourth wiring 72 and a thickness of twelfth wiring portion 74 are, for example, greater than or equal to 0.1 μm and less than or equal to 5.0 μm and preferably greater than or equal to 0.1 μm and less than or equal to 1.0 μm.

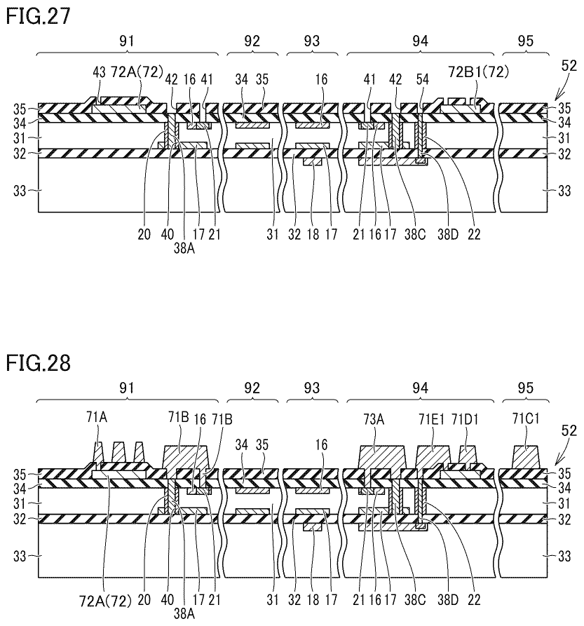

Next, as illustrated in FIG. 27, contact hole 41 extending through third insulating layer 35 and first insulating layer 34, and contact holes 42 and 43, and via holes 53 extending through third insulating layer 35 are formed. Further, second contact region 21 is formed in first doped region 16.

Each via hole 53 is a through hole for electrically connecting ninth wiring portion 71E1 to plug 38D. Via holes 53 are simultaneously formed by, for example, the same dry etching process as for contact holes 41, 42, and 43.

Next, as illustrated in FIG. 28, third wiring 71 is formed on third insulating layer 35, Third wiring 71 can be formed in the same manner as first wiring 39 of optical scanning device 1. A material constituting third wiring 71 may be any conductive material, and includes, for example, at least one of Ti, aluminum (Al), or copper (Cu). Third wiring 71 is, for example, a multilayer body in which a first layer made of a material high in adhesion to a base such as third insulating layer 35, fourth wiring 72, and second contact region 21, a second layer made of a material high in electrical conductivity, and a third layer made of a material high in corrosion resistance are laminated in this order.

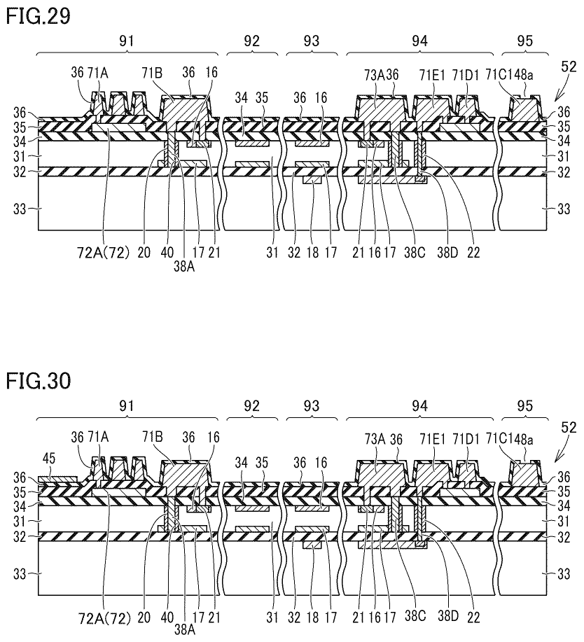

Next, as illustrated in FIG. 29, fourth insulating layer 36 is formed.

As a result, first drive portion 67 and second drive portion 68 (see FIG. 17) are formed on SOI substrate 52.

Next, as illustrated in FIG. 30, reflection film 45 is formed on fourth insulating layer 36 in region 91.

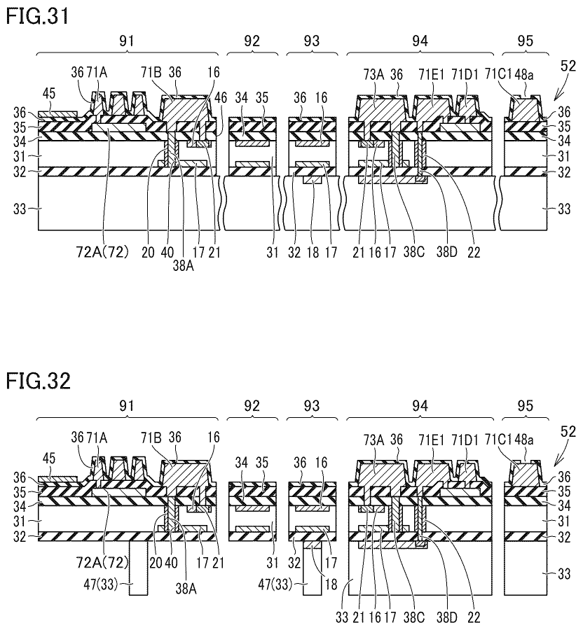

Next, as illustrated in FIG. 31, fourth insulating layer 36, third insulating layer 35, first insulating layer 34, first semiconductor layer 31, and second insulating layer 32 are patterned by a dry etching process.

Next, as illustrated in FIG. 32, after an etching mask is formed by photolithography, second semiconductor layer 33 is patterned by a dry etching process. As a result, a structure including reflector 62, first support 66, second support 63, the plurality of first drive beams 64A and 64B, and the plurality of second drive beams 65A and 65B is formed from SOI substrate 52.

In order to increase rigidity of reflector 62 and second drive beams 65A and 65B, rib 47 is formed on respective second insulating layers 32 of reflector 62 and second drive beams 65A and 65B.

Next, a structure including the structure including reflector 62, first support 66, second support 63, the plurality of first drive beams 64A and 64B, and the plurality of second drive beams 65A and 65B is taken out as a chip from SOI substrate 52, As described above, optical scanning device 1 illustrated in FIGS. 17 to 19 is manufactured.

In optical scanning device 10, first doped region 16 and second doped region 17 are electrically connected in parallel between the first conductive portion and the second conductive portion, as with optical scanning device 1. Therefore, optical scanning device 10 can produce the same effect as produced by optical scanning device 1.

Furthermore, in optical scanning device 10, third doped region 18 disposed in second drive beams 65A and 65B is electrically isolated from each of first doped region 16 and second doped region 17 disposed in second drive beams 65A and 65B, so that, when third doped region 18 is configured as a part of first drive portion 67, and first doped region 16 and second doped region 17 are configured as a part of second drive portion 68, reflector 62 can be driven around two axes.

### Modification

Each of second drive beams 65A and 65B of optical scanning device 10 according to the second embodiment may further include a fourth doped region disposed apart from third doped region 18 in the laminating direction in addition to third doped region 18. Third doped region 18 and the fourth doped region may be electrically connected in parallel between the first conductive portion and the second conductive portion in first drive portion 67. In this case, the fourth doped region may be formed, for example, at an interface between the back surface of second semiconductor layer 33 and a fifth insulating layer formed on the back surface.

Optical scanning devices 1 and 10 according to the first and second embodiments may include a drive portion of a piezoelectric drive type or electrostatic drive type instead of drive portion 5 of an electromagnetic drive type or first drive portion 67 and second drive portion 68 of an electromagnetic drive type.

The drive portion of a piezoelectric drive type includes a piezoelectric film disposed in a part of each drive beam, and the first doped region and the second doped region disposed in other part of each drive beam and electrically connected to the piezoelectric film. The first doped region and the second doped region may be formed at any one of the interface between first insulating layer 34 and first semiconductor layer 31, the interface between first semiconductor layer 31 and second insulating layer 32, or the interface between second insulating layer 32 and second semiconductor layer 33.

The piezoelectric film has a capability of converting an electric signal into a stress, and is formed on the front surface of each drive beam. As the piezoelectric film, for example, lead zirconate titanate (Pb(Zr, Ti)O₃: PZT), aluminum nitride (AlN), or the like is used. When a voltage is applied to the piezoelectric film, a film stress is produced, and the drive beam is deformed due to the inverse piezoelectric effect. The reflector is driven by the deformation of the drive beam.

The drive portion of an electrostatic drive type includes a fixed interdigital electrode, a movable interdigital electrode, and the first doped region and the second doped region electrically connected to at least the movable interdigital electrode. In optical scanning device 1, the fixed interdigital electrode is formed in support 3, and the movable interdigital electrode is formed in reflector 2. In optical scanning device 10, the fixed interdigital electrode is formed on each of first support 66 and second support 63, and the movable interdigital electrode is formed on each of reflector 62 and first support 66. The reflector is driven to twist around each drive beam by electrostatic force of charges produced by a voltage applied to the fixed interdigital electrode and a voltage applied to the movable interdigital electrode.

Optical scanning devices 1 and 10 according to the first and second embodiments are examples of the MEMS element according to the present embodiment. The MEMS element according to the present embodiment is also applicable to a pressure sensor element, an infrared sensor element, and the like. In this case, first doped region 16, second doped region 17, and third doped region 18 constitute at least a part of a wiring portion electrically connected to a piezoelectric element, or a wiring portion electrically connected to a photoelectric element (light receiving element) sensitive to the infrared band or a thermoelectric element.

### Third Embodiment

Here, a distance measuring device to which optical scanning devices 1 and 10 described in each embodiment are applied will be described.

The distance measuring device is a device that measures a distance from a light source to an object by irradiating the object with light from the light source and receiving light reflected by the object. The light reflected by the object is called return light.

For example, a distance measuring device using laser light has been recently applied to automated vehicle driving. In the distance measuring device, the presence or absence of an obstacle is detected on the basis of whether or not reflected light is received after emission of the laser light. Furthermore, in the distance measuring device, a distance from the obstacle is calculated on the basis of a time difference between the light emission timing of the laser light and the light reception timing of the reflected light.

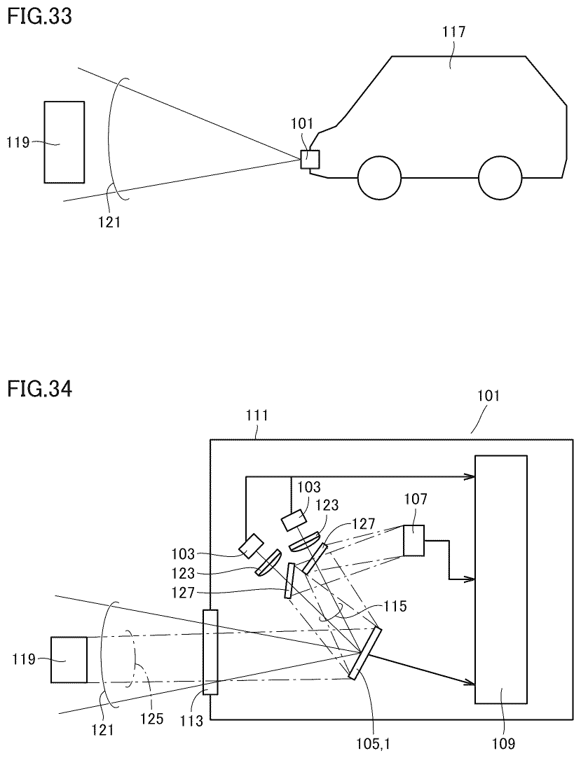

Hereinafter, a distance measuring device according to a third embodiment will be described. FIG. 33 schematically illustrates a vehicle 117 equipped with a distance measuring device 101. As illustrated in FIG. 33, distance measuring device 101 is installed at a front side of vehicle 117, for example. Distance measuring device 101 detects an object 119 located ahead. Distance measuring device 101 calculates a distance from vehicle 117 to object 119. Object 119 is, for example, another vehicle, a bicycle, a pedestrian, or the like. In distance measuring device 101, emission light 121 is emitted, and reflected light 125 (see FIG. 34) from object 119 is detected. In distance measuring device 101, a distance image is created on the basis of reflected light 125 thus detected.

### (Overall Configuration of Distance Measuring Device)

FIG. 34 schematically illustrates a configuration of distance measuring device 101. Distance measuring device 101 includes a plurality of light sources 103, a lens 123, a mirror 105 (light emission side), a mirror 127 (light reception side), a light receiver 107, and a controller 109. For example, optical scanning device 1 described in the first embodiment and the like is used as mirror 105. Such optical systems are accommodated in a housing 111. Housing 111 is provided with a window 113. Hereinafter, each component will be described in detail.

### (Light Source)

Light source 103 emits light 115. Light source 103 is, for example, a laser light source or the like. Distance measuring device 101 may include a plurality of light sources 103. In FIG. 34, two light sources 103 are illustrated, but the number of light sources may be one.

### (Light)

Light 115 is laser light emitted from light source 103. A wavelength of the laser light is, for example, about 870 nm to 1500 nm.

### (Lens)

Lens 123 changes a light distribution of light 115 emitted from light source 103. The light distribution refers to a spatial distribution of light emitted from a light source in each direction. Lens 123 changes the light distribution to collimate emission light 121 emitted from distance measuring device 101. Lens 123 is, for example, a convex lens, a cylindrical lens, a toroidal lens, or the like. As lens 123, two or more lenses may be used. Note that lens 123 may be removed if emission light 121 is emitted from distance measuring device 101 as collimated light.

### (Mirror)

Mirror 105 is reflection surface 45a (see FIGS. 1 and 17) of reflectors 2 and 62 of optical scanning devices 1 and 10 according to the first and second embodiments. Mirror 105 reflects light 115 emitted from light source 103 and passing through lens 123. Light 115 reflected by mirror 105 is emitted from distance measuring device 101 as emission light 121.

Reflectors 2 and 62 each having reflection surface 45a serving as mirrors 105 are driven to twist (rotate) around each drive beam 4, 64, and 65 (see FIGS. 1 and 17), The twisting drive is reciprocating motion. Emission light 121 is two-dimensionally scanned by the twisting drive of mirror 105. Light 115 emitted from the plurality of light sources 103 is reflected by mirror 105 in different directions.

### (Emission Light)

Emission light 121 is laser light emitted from distance measuring device 101. Emission light 121 includes light 115 emitted from the plurality of light sources 103 and reflected by mirror 105. Emission light 121 is collimated light. A beam waist where a beam of emission light 121 is the smallest in width is set at, for example, 60 m ahead. Emission light 121 is pulsed light. A pulse width is, for example, 1 ns to 10 ns. Object 119 is irradiated with emission light 121.

### (Reflected Light)

Reflected light 125 is light (component) that travels from object 119 toward distance measuring device 101 out of light reflected by object 119 after emission light 121 is emitted to object 119.

### (Light Receiver)

Light receiver 107 detects light. Light receiver 107 includes, for example, a light receiving element that detects light. The light receiving element is, for example, a photodiode, an avalanche photodiode, or the like. Light receiver 107 detects reflected light 125 that travels from object 119 toward distance measuring device 101 and is reflected by mirror 105 and mirror 127.

Note that reflected light 125 reflected by mirror 105 travels toward light source 103, so that light receiver 107 may be disposed near light source 103. Installing mirror 127 allows light receiver 107 to be disposed apart from light source 103. A lens (not illustrated) that concentrates reflected light 125 may be disposed in light receiver 107.

### (Mirror)

Mirror 127 reflects reflected light 125 reflected by mirror 105 toward light receiver 107. Mirror 127 desirably has, for example, a through hole formed at its center so as to allow light 115 emitted from light source 103 pass through. Further, mirror 127 may be one or a plurality of mirrors disposed at a position away from an optical path of light 115 emitted from light source 103. Further, mirror 127 may be a half mirror or a beam splitter that transmits a part of the emitted light and reflects a part of the emitted light. Mirror 127 may have a capability of concentrating light.

### (Controller)

Controller 109 controls the operation of distance measuring device 101 including light source 103, mirror 105, and light receiver 107. For example, controller 109 controls the emission timing of pulsed light 115 that is emitted from light source 103 and detects the emission timing. Controller 109 controls the drive of mirror 105, and detects a tilt angle of and an angle of the normal to mirror 105. Controller 109 detects a light-receiving status of light receiver 107.

### (Housing)

Housing 111 is an outer casing that accommodates the optical systems of distance measuring device 101. The optical systems including the plurality of light sources 103, mirror 105, light receiver 107, and the like are accommodated in housing 111. Housing 111 is lightproof. An inside of housing 111 is desirably black to absorb stray light. Housing 111 is provided with window 113 through which emission light 121 and reflected light 125 pass.

### (Window)

Window 113 is an opening, and emission light 121 is emitted toward object 119 through window 113. Reflected light 125 enters housing 111 through window 113. Window 113 desirably shields light from the outside of housing 111. A window member having a wavelength characteristic corresponding to a wavelength of light to be allowed to pass through is attached to window 113. As the window member, a window member having a wavelength characteristic for allowing light 115 to pass through is attached.

Note that an optical system in which the optical path of emission light 121 and the optical path of reflected light 125 are different may be employed, and a plurality of windows including a window for emission light 121 and a window for reflected light 125 may be provided as window 113. Window 113 may have a capability of concentrating light or a capability of diverging light.

### (Operation of Distance Measuring Device)

Next, an example of the operation of distance measuring device 101 will be described. As illustrated in FIG. 34, the light distribution of light 115 emitted from light source 103 is changed by lens 123. Light 115 passing through lens 123 becomes, for example, collimated light. Light 115 that has become collimated light passes through mirror 127 or passes through a through hole (not illustrated) provided in mirror 127, and is reflected by mirror 105.

Light 115 reflected by mirror 105 is emitted from distance measuring device 101 toward object 119 as emission light 121. Here, mirror 105 corresponds to reflectors 2 and 62 of optical scanning devices 1 and 10 (see FIGS. 1 and 17), and light 115 is two-dimensionally or three-dimensionally scanned by the twisting drive of reflectors 2 and 62, Light 115 two-dimensionally or three-dimensionally scanned is emitted toward object 119 through window 113 as emission light 121.

Emission light 121 emitted to object 119 is reflected by object 119. A part of the reflected light, that is, reflected light 125, enters housing 111 of distance measuring device 101 through window 113. Reflected light 125 that has entered housing 111 is reflected by mirror 105 and further reflected by mirror 127 to impinge on light receiver 107. Light receiver 107 detects reflected light 125 that has impinged. Controller 109 measures a time from the emission of light 115 from light source 103 to the detection of light 115 by light receiver 107. Controller 109 calculates a distance from vehicle 117 to object 119 on the basis of the time thus measured.

Controller 109 detects a direction of the normal to mirror 105 (reflectors 2, 62) that is driven to twist. In this case, for example, a sensor that detects a cycle of the twisting drive of mirror 105 can be used. Furthermore, controller 109 can detect the direction of the normal from a drive signal for mirror 105. Controller 109 calculates an emission direction of emission light 121 on the basis of the position of light source 103 and the direction of the normal to mirror 105.

Controller 109 calculates a direction of a position at which object 119 is located relative to vehicle 117 and a distance to the position on the basis of the emission direction of emission light 121 and the distance to object 119. Controller 109 calculates the direction of the position at which object 119 is located relative to vehicle 117 and the distance to the position on the basis of emission light 121 that is scanned without interruption and reflected light 125 that is detected to obtain a distance image.

Note that, in distance measuring device 101 described above, the optical system for emission light 121 and the optical system for reflected light 125 are the same optical system, but the optical system for reflected light 125 may be an optical system different from the optical system for emission light 121. Even with such optical systems, the distance to the object can be calculated on the basis of emission light 121 and reflected light 125 that is detected. Furthermore, it is possible to obtain a distance image of surroundings of distance measuring device 101 (vehicle 117) including object 119 on the basis of emission light 121 that is scanned without interruption and reflected light 125 that is detected.

The embodiments disclosed herein are illustrative and are not construed as limiting the present disclosure. The scope of the present disclosure is defined by the claims rather than the above description, and the present disclosure is intended to include the claims, equivalents of the claims, and all modifications within the scope.

### REFERENCE SIGNS LIST

1, 10: optical scanning device, 2, 62: reflector, 3: support, 4, 4A, 48, 64, 64A, 64B, 65, 65A, 65B: drive beam, 5: drive portion, 6, 69, 70: magnet, 11: first silicon substrate, 12: second silicon substrate, 13: first bonding film, 14: second bonding film, 15: alignment mark, 16: first doped region, 17: second doped region, 18: third doped region, 20: first contact region, 21: second contact region, 22: third contact region, 23: fourth contact region, 31: first semiconductor layer, 32: second insulating layer, 33: second semiconductor layer, 34: first insulating layer, 35: third insulating layer, 36: fourth insulating layer, 37: second wiring, 38A, 38B, 38C, 38D: plug, 39: first wiring, 39A: first wiring portion, 391: second wiring portion, 39C: third wiring portion, 40, 53: via hole, 41, 42, 43, 44, 53: contact hole, 44a, 44b, 4811, 48a, 48b, 4911, 49a, 49b: electrode pad, 45: reflection film, 45a: reflection surface, 46: sidewall surface, 47: rib, 51, 52: SOI substrate, 63: second support, 66: first support, 67: first drive portion, 68: second drive portion, 71: third wiring, 71A: fourth wiring portion, 71B: sixth wiring portion, 71C1, 71C2: seventh wiring portion, 71D1, 71D2: eighth wiring portion, 71E1, 71E, 71E2: ninth wiring portion, 72: fourth wiring, 72A: fifth wiring portion, 72112, 72B1: tenth wiring portion, 73: fifth wiring, 73A: eleventh wiring portion, 7311: thirteenth wiring portion, 73C1, 73C2: fourteenth wiring portion, 74: twelfth wiring portion, 101: distance measuring device, 103: light source, 105, 127: mirror, 107: light receiver, 109: controller, 111: housing, 113: window, 115: light, 117: vehicle, 119: object, 121: emission light, 123: lens, 125: reflected light

1. A MEMS element comprising:
a driven portion;
a support disposed apart from the driven portion;
a drive beam connecting the driven portion and the support; and
a drive portion to drive the driven portion to twist the driven portion around the drive beam relative to the support, wherein
the drive portion includes a first conductive portion disposed in the driven portion, a second conductive portion disposed in the support, and a wiring portion disposed at least in the drive beam and connecting the first conductive portion and the second conductive portion,
the drive beam includes:
a first insulating layer, an active layer, a second insulating layer, and a support layer that are laminated in this order;
a first doped region and a second doped region formed at any one of an interface between the first insulating layer and the active layer, an interface between the active layer and the second insulating layer, and an interface between the second insulating layer and the support layer, and disposed apart from each other in a laminating direction of the first insulating layer, the active layer, the second insulating layer, and the support layer wherein
the first doped region and the second doped region serve as at least a part of the wiring portion, and are electrically connected in parallel between the first conductive portion and the second conductive portion.

2. The MEMS element according to claim 1, wherein
the first doped region and the second doped region are disposed in alignment with each other in the laminating direction.

3. A MEMS element comprising:
a first insulating layer, an active layer, a second insulating layer, and a support layer that are laminated in this order;
a first doped region and a second doped region formed at any one of an interface between the first insulating layer and the active layer, an interface between the active layer and the second insulating layer, and an interface between the second insulating layer and the support layer, and disposed apart from each other in a laminating direction of the first insulating layer, the active layer, the second insulating layer, and the support layer; and
a first conductive portion and a second conductive portion disposed apart from each other on the first insulating layer, wherein
the first doped region and the second doped region are electrically connected in parallel between the first conductive portion and the second conductive portion,
the MEMS element further comprising a third doped region formed at any one of the interface between the first insulating layer and the active layer, the interface between the active layer and the second insulating layer, and the interface between the second insulating layer and the support layer, and disposed in alignment with the first doped region and the second doped region in the laminating direction, wherein
the first doped region, the second doped region, and the third doped region are electrically connected in parallel between the first conductive portion and the second conductive portion.

4. The MEMS element according to claim 1, further comprising a fourth doped region formed at any one of the interface between the first insulating layer and the active layer, the interface between the active layer and the second insulating layer, and the interface between the second insulating layer and the support layer, and disposed in alignment with the first doped region and the second doped region in the laminating direction, wherein
the fourth doped region is electrically isolated from the first doped region, the second doped region, the first conductive portion, and the second conductive portion.

5. The MEMS element according to claim 1, further comprising:
a first via hole and a second via hole formed in the active layer, the first via hole connecting the first conductive portion and the second doped region, the second via hole connecting the second conductive portion and the second doped region, the active layer having a first conductivity type, and the second doped region having a second conductivity type different from the first conductivity type; and
a contact region formed on an inner peripheral surface of each of the first via hole and the second via hole and having the second conductivity type.

6. The MEMS element according to claim 1, wherein
an impurity concentration of the first doped region and an impurity concentration of the second doped region are greater than or equal to 1*10¹⁸ atoms/cm³.

7. The MEMS element according to claim 1, wherein
a thickness of the active layer in the laminating direction is greater than or equal to 10 μm.

8. The MEMS element according to claim 3, further comprising:
a reflector including the first insulating layer, the active layer, the second insulating layer, and the first conductive portion, and having a reflection surface disposed on the first insulating layer side by side with the first conductive portion;
a support including the first insulating layer, the active layer, the second insulating layer, and the second conductive portion, and disposed apart from the reflector; and
a drive beam including respective remaining parts of the first insulating layer, the active layer, the second insulating layer, the first doped region, and the second doped region, and connecting the reflector and the support.

9. The MEMS element according to claim 8, wherein
no conductive layer is disposed on the first insulating layer and the second insulating layer of the drive beam.

10. An optical scanning device comprising:
a reflector having a reflection surface;
a support disposed apart from the reflector;
a drive beam connecting the reflector and the support; and
a drive portion to drive the reflector to twist the reflector around the drive beam relative to the support, wherein
the drive portion includes a first conductive portion disposed in the reflector, a second conductive portion disposed in the support, and a wiring portion disposed at least in the drive beam and connecting the first conductive portion and the second conductive portion,
the drive beam includes:
a first insulating layer, a semiconductor layer, and a second insulating layer that are laminated in this order;
a first doped region formed at an interface between the first insulating layer and the semiconductor layer; and
a second doped region formed at an interface between the semiconductor layer and the second insulating layer, and
the first doped region and the second doped region serve as at least a part of the wiring portion, and are electrically connected in parallel between the first conductive portion and the second conductive portion.

11. The optical scanning device according to claim 10, wherein
the reflector, the support, and the drive beam each further include:
a support layer disposed adjacent to a side of the second insulating layer remote from the semiconductor layer and in contact with the second insulating layer; and
a third doped region formed at an interface between the second insulating layer and the support layer,
the wiring portion further includes the third doped region, and
the first doped region, the second doped region, and the third doped region are electrically connected in parallel between the first conductive portion and the second conductive portion.

12. The optical scanning device according to claim 10, wherein
the support includes:
a first support disposed so as to surround the reflector in plan view; and
a second support disposed outside the first support in plan view, the second support having the second conductive portion disposed therein,
the drive beam includes:
a first drive beam connecting the reflector and the first support; and
a second drive beam connecting the first support and the second support,
the drive portion includes a first drive portion to drive the reflector to twist the reflector around the first drive beam, and a second drive portion to drive the reflector and the first support to twist the reflector and the first support around the second drive beam,
the first drive portion includes the first conductive portion disposed in the reflector, the second conductive portion disposed in the second support, and a first wiring portion disposed at least in each of the first drive beam and the second drive beam and connecting the first conductive portion and the second conductive portion,
the second drive portion includes a third conductive portion disposed in the first support, a fourth conductive portion disposed in the second support, and a second wiring portion disposed at least in the second drive beam and connecting the third conductive portion and the fourth conductive portion,
the reflector, the first drive beam, the first support, the second drive beam, and the second support each include the first insulating layer, the first doped region, the semiconductor layer, the second doped region, and the second insulating layer,
the first support, the second drive beam, and the second support each further include:
a support layer disposed adjacent to a side of the second insulating layer remote from the semiconductor layer and in contact with the second insulating layer; and
a fourth doped region formed at an interface between the second insulating layer and the support layer,
the fourth doped region is electrically isolated from the first doped region, the second doped region, the first conductive portion, and the second conductive portion,
the first wiring portion includes the first doped region and the second doped region, and
the second wiring portion includes the fourth doped region.

13. The optical scanning device according to claim 10, wherein
no conductive layer is disposed on the first insulating layer and the second insulating layer of the drive beam.

14. A distance measuring device to which an optical scanning device according to claim 10 is applied, the distance measuring device comprising:
a light source to emit light toward the optical scanning device;
the optical scanning device to reflect the light toward an object;
a photodetector to detect the light reflected by the object; and
a controller to control operation of the optical scanning device.

15. (canceled)

16. The MEMS element according to claim 1, wherein
no conductive layer is disposed on the first insulating layer and the second insulating layer of the drive beam.

17. The MEMS element according to claim 3, wherein
the first doped region and the second doped region are disposed in alignment with each other in the laminating direction.

18. The MEMS element according to claim 3, further comprising a fourth doped region formed at any one of the interface between the first insulating layer and the active layer, the interface between the active layer and the second insulating layer, and the interface between the second insulating layer and the support layer, and disposed in alignment with the first doped region and the second doped region in the laminating direction, wherein
the fourth doped region is electrically isolated from the first doped region, the second doped region, the first conductive portion, and the second conductive portion.

19. The MEMS element according to claim 3, further comprising:
a first via hole and a second via hole formed in the active layer, the first via hole connecting the first conductive portion and the second doped region, the second via hole connecting the second conductive portion and the second doped region, the active layer having a first conductivity type, and the second doped region having a second conductivity type different from the first conductivity type; and
a contact region formed on an inner peripheral surface of each of the first via hole and the second via hole and having the second conductivity type.

20. The MEMS element according to claim 3, wherein
an impurity concentration of the first doped region and an impurity concentration of the second doped region are greater than or equal to 1*10¹⁸ atoms/cm³.

21. The MEMS element according to claim 4, wherein
an impurity concentration of the first doped region and an impurity concentration of the second doped region are greater than or equal to 1*10¹⁸ atoms/cm³.
